(19) United States
(12) Patent Application Publication
(10) Pub. No.: US 2024/0401838 A1
(43) Pub. Date: Dec. 5, 2024

(54) BATTERYLESS ULTRA-LOW POWER ADJUSTABLE TEMPERATURE-HUMIIDTY SENSOR SWITCH

(71) Applicant: Solar Royal, LLC, Austin, TX (US)

(72) Inventor: ROY R. STOCKER, AUSTIN, TX (US)

(21) Appl. No.: 18/677,787

(22) Filed: May 29, 2024

Related U.S. Application Data
(60) Provisional application No. 63/469,663, filed on May 30, 2023.

(51) Int. Cl. F24F 11/88; F24F 7/02; F24F 11/00; F24F 11/56; F24F 110/10; F24F 110/20; H02S 20/30; H03K 17/94

(52) U.S. Cl. CPC F24F 11/88; F24F 7/025; F24F 11/0001; F24F 11/56; H03K 17/94; F24F 2110/10; F24F 2110/20; F24F 2221/16; H02S 20/30

(57) ABSTRACT

Switches are disclosed that have a power conductor configured to receive power from a batteryless ultra-low power direct current power source. Such switches also include an output conductor configured to provide a switch signal and include one or more environmental sensors for measuring temperature and humidity. The environmental sensor is capable of generating an environmental signal in dependence upon the measured temperature and humidity. Such switches also include an adjustable configuration module that allows a user to specify environmental threshold parameters. Such switches also include circuitry operatively connected to the power conductor, the output conductor, the environmental sensor, and the adjustable configuration module. The circuitry sets the switch signal in dependence upon the environmental signals and the environmental threshold parameters.

### CROSS REFERENCE TO RELATED APPLICATIONS

This application is a continuation-in-part of and claims the benefit of U.S. provisional patent application No. 63/469,663 filed on May 30, 2023; the disclosure of which are hereby incorporated by reference in their entirety as though the same were reproduced herein verbatim.

This application is a continuation-in-part of and claims the benefit of, U.S. non-provisional patent application Ser. No. 18/375,541 filed on Oct. 1, 2023, which is a continuation of and claims the benefit of, U.S. non-provisional patent application Ser. No. 17/018,076 filed on Sep. 11, 2020, now U.S. Pat. No. 11,788,744 issued Oct. 17, 2023, which is a continuation-in-part of and claims the benefit of U.S. non-provisional patent application Ser. No. 14/329,596 filed on Jul. 11, 2014, which claims the benefit of U.S. provisional patent application No. 61/879,439 filed on Sep. 18, 2013 and which is a continuation-in-part of U.S. application Ser. No. 29/422,087 filed on May 16, 2012, which issued as Patent No. D762835 on Aug. 2, 2016; the disclosures of which are hereby incorporated by reference in their entirety as though the same were reproduced herein verbatim.

### BACKGROUND OF THE INVENTION

Temperature and humidity sensing devices play a crucial role in numerous industries, including HVAC (Heating, Ventilation, and Air Conditioning), agriculture, pharmaceuticals, and food storage, among others. These devices enable the measurement and control of environmental conditions to ensure optimal performance, safety, and efficiency.

Traditionally, temperature and humidity sensors have been implemented using different technologies, such as resistive, capacitive, and semiconductor-based sensors. These sensors generate electrical signals proportional to the measured environmental parameters and are integrated into switching circuits to provide control functionalities.

A common challenge encountered with existing temperature and humidity sensor switches is the high power consumption associated with their operation. Many conventional sensing devices require significant amounts of power to function, leading to increased energy consumption and limited battery life in portable applications. This limitation restricts their effectiveness in environments where power sources are scarce or where long-term operation is essential.

Another issue with existing temperature and humidity sensor switches is the lack of adjustability. Often, these sensors come with fixed temperature and humidity thresholds, limiting their versatility in accommodating different application requirements. This lack of adjustability restricts their use in scenarios where customized threshold values are necessary to trigger specific actions or alerts.

### SUMMARY

The following presents a simplified summary in order to provide an understanding of some aspects of the disclosed subject matter. This summary is not an extensive overview of the disclosed subject matter, and is not intended to identify key/critical elements or to delineate the scope of such subject matter. A purpose of the summary is to present some concepts in a simplified form as a prelude to the more detailed disclosure that is presented herein.

An exemplary batteryless ultra-low power adjustable temperature-humidity sensor switch includes a power conductor configured to receive power from a batteryless ultra-low power direct current power source and includes an output conductor configured to provide a switch signal. An exemplary switch also includes environmental sensors for measuring temperature and humidity. The exemplary environmental sensors are capable of generating one or more environmental signals in dependence upon the measured temperature and humidity. An exemplary switch includes an adjustable configuration module that allows a user to specify environmental threshold parameters. An exemplary switch includes circuitry operatively connected to the power conductor, the output conductor, the one or more environmental sensors, and the adjustable configuration module. The exemplary circuitry is configured to set the switch signal in dependence upon the one or more environmental signals and the environmental threshold parameters.

The exemplary the direct current power source may include one or more solar cells. The exemplary environmental threshold parameters may be implemented as temperature threshold parameters or humidity threshold parameters. The exemplary environmental sensor may be configured to operate solely on ultra-low power derived from the direct current power source. The adjustable configuration module may be configured to operate solely on ultra-low power derived from the batteryless ultra-low power direct current power source. The exemplary circuitry may be configured to operate solely on ultra-low power derived from the batteryless ultra-low power direct current power source.

The exemplary output conductor may provide the switch signal to a motor, which activates the motor. The exemplary motor may be part of an attic ventilation system such that the attic ventilation system is configured to turn on a fan upon activation of the motor by the switch signal.

The exemplary switch may include a communications module operatively connected to the adjustable configuration module. Such a communications module may be configured to receive updates to the environmental threshold parameters from a remote device operated by the user.

In exemplary switches, the adjustable configuration module may include user-adjustable switches. Each of the plurality of user-adjustable switches may correspond to a specific environmental threshold parameter allowing the user to set the environmental threshold parameters by manipulating the user-adjustable switches.

In some exemplary switches, the circuitry may be configured to set the switch signal only when the power source provides sufficient power for the circuitry to operate. This ensures that the switch operates solely on the ultra-low power derived from the power source rather than any batteries.

In other exemplary switches, the environmental threshold parameters may include a temperature threshold parameter and a humidity threshold parameter. In such exemplary switches, the circuitry may include an ultra-low power microcontroller configured to compare the one or more environmental signals to both the temperature threshold parameter and the humidity threshold parameter, and to set the switch signal based on the comparison.

In still other exemplary switches where the environmental threshold parameters also include a temperature threshold parameter and a humidity threshold parameter, the adjustable configuration module may be configured to allow the user to specify the temperature threshold parameter and the humidity threshold parameter. The exemplary circuitry of such switches may be configured to set the switch signal to a first state when both the temperature threshold parameter and the humidity threshold parameter are exceeded, and to a second state when either the temperature threshold parameter or the humidity threshold parameter is not exceeded. Alternatively, the exemplary circuitry of such switches may be configured to set the switch signal to a first state when either the temperature threshold parameter or the humidity threshold parameter are exceeded.

In still other exemplary switches where the environmental threshold parameters also include a temperature threshold parameter and a humidity threshold parameter, the environmental sensors may include a combined temperature and humidity sensor capable of generating a first environmental signal corresponding to temperature and a second environmental signal corresponding to humidity. The exemplary circuitry may be configured to set the switch signal based on a comparison of the first environmental signal to the temperature threshold parameter and a comparison of the second environmental signal to the humidity threshold parameter.

In still other exemplary switches, the switch includes a power conductor configured to receive power from a batteryless ultra-low power direct current power source. Such an exemplary switch includes an output conductor configured to provide a switch signal to a motor of an attic ventilation system. The attic ventilation system in such an example is configured to start a fan upon activation of the motor by the switch signal. Such an exemplary switch includes environmental sensors for measuring temperature and humidity, the one or more environmental sensors capable of generating one or more environmental signals in dependence upon the measured temperature and humidity. Such an exemplary switch also includes an adjustable configuration module that allows a user to specify environmental threshold parameters. Such an exemplary switch further includes circuitry operatively connected to the power conductor, the output conductor, the one or more environmental sensors, and the adjustable configuration module. The exemplary circuitry may be configured to set the switch signal in dependence upon the one or more environmental signals and the environmental threshold parameters. The exemplary attic ventilation system may include a base unit having a mounting platform for connecting the base unit to a surface having a surface opening. The base unit may have a base collar extending away from the mounting platform where the base collar forms a perimeter of a base opening through the base unit that corresponds to the surface opening. The exemplary attic ventilation system may include a fan unit comprising a fan housing and a fan. The fan housing may be configured to receive air through an inlet and expel the air through an outlet. The exemplary fan is capable of connecting to a power source that enables the fan to move the air from the inlet to the outlet. Such an exemplary fan housing may include a fan housing base. The exemplary attic ventilation system may include a quick connect interface having a base feature and a fan housing feature where the base feature is integrated into the base unit and the housing feature is integrated into the fan unit. The base feature and the fan housing feature may be capable of detachably connecting together to secure the fan unit to the base unit. The fan housing feature of the quick connect interface may be integrated into the fan housing base.

Exemplary batteryless ultra-low power adjustable temperature-humidity switching methods according to embodiments of the present invention are also described. Such exemplary methods include receiving, by a power conductor, power from a batteryless ultra-low power direct current power source; measuring, by one or more environmental sensors, temperature and humidity; generating, by the one or more environmental sensors, one or more environmental signals in dependence upon the measured temperature and humidity; specifying, by a user using an adjustable configuration module, environmental threshold parameters; comparing, by circuitry operatively connected to the power conductor, an output conductor, the one or more environmental sensors, and the adjustable configuration module, the one or more environmental signals to the environmental threshold parameters; and setting, by the circuitry, a switch signal on the output conductor in dependence upon the comparison of the one or more environmental signals and the environmental threshold parameters.

In some exemplary methods, the batteryless ultra-low power direct current power source may include one or more solar cells, and the environmental threshold parameters may include a temperature threshold parameter and a humidity threshold parameter. In such exemplary methods, comparing, by the circuitry, may be carried out by comparing a first environmental signal of the one or more environmental signals to the temperature threshold parameter, and comparing a second environmental signal of the one or more environmental signals to the humidity threshold parameter. Further in those exemplary methods, setting, by the circuitry, the switch signal may be carried out by setting the switch signal to a first state when both the first environmental signal exceeds the temperature threshold parameter and the second environmental signal exceeds the humidity threshold parameter, and setting the switch signal to a second state when either the first environmental signal does not exceed the temperature threshold parameter or the second environmental signal does not exceed the humidity threshold parameter.

### BRIEF DESCRIPTION OF THE DRAWINGS

The detailed description is described with reference to the accompanying figures.

FIG. 1 Prior Art illustrates a building.

FIG. 2 Prior Art illustrates a user installing a roof-mounted fan system.

FIG. 3 Prior Art further illustrates a user installing a roof-mounted fan system.

FIG. 4 Prior Art still further illustrates a user installing a roof-mounted fan system.

FIG. 5 illustrates a two-piece fan system with a solar panel in an extended position.

FIG. 6 further illustrates a two-piece fan system with a solar panel in a stowed position.

FIG. 7 illustrates aspects of a two-piece fan system.

FIG. 8 illustrates a fan assembly of a two-piece fan system.

FIG. 9 illustrates a top plan view of a housing of a two-piece fan system.

FIG. 10 further illustrates an exploded view of a fan assembly for a two-piece fan.

FIG. 11 illustrates a cross-sectional view of a two-piece fan system.

FIG. 12 illustrates a top plan view of a pair of closures for two-piece fan systems.

FIG. 13 illustrates an exploded view of a two-piece fan system.

FIG. 14 illustrates a two-piece fan system installed on a roof.

FIG. 15 illustrates an exploded view of a two-piece fan system with a riser.

FIG. 16 illustrates a two-piece fan system with a riser installed on a roof.

FIG. 17 illustrates a corrugated roof and bases for two-piece fan systems.

FIG. 18 illustrates one half of a quick attachment coupling for two-piece fan systems.

FIG. 18A illustrates a cross-sectional view as seen along line AA in FIG. 18.

FIG. 19 illustrates another two-piece fan system and a roof curb.

FIG. 19A illustrates a cross-sectional view of the base of FIG. 19.

FIG. 20 illustrates a schematic of a circuit associated with a two-piece fan system.

FIG. 21 illustrates a flowchart of a method related to two-piece fan systems.

FIG. 22 illustrates a quick attachment coupling for multi-piece fans.

FIG. 23 illustrates a perspective view of an exemplary ventilation system according to embodiments of the present invention.

FIG. 24 illustrates a left view of the exemplary base unit useful in ventilation systems according to embodiments of the present invention.

FIG. 25 illustrates a perspective view of the exemplary base unit useful in ventilation systems according to embodiments of the present invention.

FIG. 25A illustrates a magnified view of an exemplary base feature shown in FIG. 25.

FIG. 26 illustrates a perspective view of the exemplary fan unit useful in ventilation systems according to embodiments of the present invention.

FIG. 26A illustrates an exploded view of the exemplary fan unit shown in FIG. 26.

FIG. 27 illustrates a top view of the airflow diverter of FIG. 26A.

FIG. 27A illustrates a cross-sectional view of the airflow diverter of FIG. 27 along line B-B.

FIG. 28 illustrates a perspective view of the exemplary fan housing base of a fan unit useful in ventilation systems according to embodiments of the present invention.

FIG. 28A illustrates a magnified view of the exemplary fan housing feature of FIG. 28.

FIG. 28B illustrates another magnified view of the exemplary fan housing feature of FIG. 28.

FIG. 28C illustrates a magnified view of the exemplary fan housing feature of FIG. 28 coupled together with an exemplary base feature according to embodiments of the present invention.

FIG. 28D illustrates another magnified view of the exemplary fan housing feature of FIG. 28 coupled together with an exemplary base feature according to embodiments of the present invention.

FIG. 29 sets forth a perspective view of a base unit useful in ventilation systems according to embodiments of the present invention.

FIG. 30 sets forth an exploded view of a base unit depicted in FIG. 29.

FIG. 31 sets forth a block diagram illustrating an exemplary ultra-low power adjustable temperature-humidity sensor switch according to embodiments of the present invention.

FIG. 32 sets forth a block diagram illustrating an exemplary power supply useful in an ultra-low power adjustable temperature-humidity sensor switch according to embodiments of the present invention.

FIG. 33 sets forth a block diagram illustrating exemplary circuitry useful in an ultra-low power adjustable temperature-humidity sensor switch according to embodiments of the present invention.

FIG. 34 sets forth a block diagram illustrating an exemplary adjustable configuration module useful in an ultra-low power adjustable temperature-humidity sensor switch according to embodiments of the present invention.

FIG. 35 sets forth a block diagram illustrating an exemplary environmental sensor useful in an ultra-low power adjustable temperature-humidity sensor switch according to embodiments of the present invention.

FIG. 36 sets forth a block diagram illustrating an exemplary switch response circuitry useful with an ultra-low power adjustable temperature-humidity sensor switch according to embodiments of the present invention.

FIG. 37 sets forth a block diagram illustrating an exemplary printed circuit board for an ultra-low power adjustable temperature-humidity sensor switch according to embodiments of the present invention.

FIG. 38 sets forth a block diagram illustrating another exemplary ultra-low power adjustable temperature-humidity sensor switch according to embodiments of the present invention.

FIG. 39 sets forth a block diagram illustrating another exemplary ultra-low power adjustable temperature-humidity sensor switch according to embodiments of the present invention.

FIG. 40 sets forth a block diagram illustrating an exemplary method of batteryless ultra-low power adjustable temperature-humidity switching according to embodiments of the present invention.

### DETAILED DESCRIPTION

The present invention relates to temperature and humidity sensing devices, specifically to batteryless ultra-low-power adjustable direct current (DC) temperature humidity sensor switches. Such devices may be widely used in various applications that require accurate monitoring and control of environmental conditions. Embodiments of the present invention combine advanced sensor technology with energy-efficient design principles to enable accurate and reliable temperature and humidity monitoring while minimizing power consumption.

Exemplary batteryless ultra-low-power adjustable direct current (DC) temperature humidity sensor switches according to embodiments of the present invention may be used in a variety of settings and have applications as part of larger systems. For example, exemplary ventilation systems for ventilating attics (and/or other spaces) and, more a particularly, multi-piece ventilations units with adjustable (and flush fitting) solar panels and/or quick attachment fittings whereby fan assemblies of the ventilation units can be quickly attached to/detached from bases of ventilation units, may also incorporate exemplary batteryless ultra-low-power adjustable direct current (DC) temperature humidity sensor switches.

### Exemplary Ventilation Systems for Ventilating Attics

Such exemplary ventilation systems for ventilating attics are further described herein. Exemplary embodiments provide two-piece fan systems for use in ventilating spaces such as attics, crawlways, etc. These fan systems can require relatively low power and can possess high reliability. Moreover, fan systems of exemplary embodiments can be powered via solar panels, solar systems, etc. and/or power systems available in the buildings in/on which they might be installed. Fan systems of exemplary embodiments can be used in residential, commercial and/or utility applications, can be thermostat controlled, and whole ventilation system can be windstorm certified per ASTM-E330 (and/or in accordance with other techniques).

Exemplary ventilation systems according to these embodiments are technologically, functionally and aesthetically superior to heretofore-available fan systems. Such exemplary ventilation systems are rugged, durable, practical, windstorm certified and relatively inexpensive to manufacture, install, operate, maintain, modify, etc. Exemplary ventilation systems according to embodiments of the present invention possess elegant low profiles, blend nicely into their environments, and can be painted to match/complement their surroundings. In addition, or in the alternative, such exemplary ventilation systems possess adjustable solar panels. Such fan systems can include adjustable brackets with multiple locking states which support the solar panels and allow their positions to be adjusted.

Exemplary ventilation systems according to embodiments of the present invention can be used to provide proper ventilation for many spaces. In some situations, these fan systems ventilate spaces to reduce temperatures inside enclosed spaces throughout the year such as attics, crawl spaces, warehouses, storage areas, sheds, barns, etc. In the summer, in particular, solar powered attic fan systems of embodiments help make such areas more comfortable by converting passive ventilation to active ventilation.

Exemplary ventilation systems according to embodiments of the present invention can reduce HVAC (heating, ventilation, and air conditioning) costs and reduce cooling cycles thereby saving energy and money. Furthermore, by reducing interior temperatures these exemplary ventilation systems can reduce premature deterioration of shingles, roof boards, sheathing, siding, insulation, stored valuables, etc. Proper ventilation can also prevent/reduce moisture (from relatively warm air) condensing on the under sides of relatively cool roofs, beams, rafters, etc. Moreover, because fan systems of some exemplary embodiments are solar powered, such exemplary embodiments can cost the owner/operator little or nothing to operate. Some exemplary embodiments include solar panels (and their adjustable brackets) to power the fan system, and those solar panels may be embedded in the fan housings rather than appearing as add-ons or appearing as if those panels have been glued onto the ventilation systems.

Some ventilation systems according to embodiments of the present invention provide two-piece ventilation units comprising bottom bases, top housings, solar panels, locks, and biasing members. The bottom bases of such exemplary embodiment may define flashing which is shaped and dimensioned to divert runoff around the fan systems. They also define riser portions extending from the flashing and further define first halves of twist-on, quick attachment couplings. The top housings of the such exemplary embodiments contain fans and define second halves of the twist-on, quick attachment couplings. The top housings are releasably coupled to the bottom bases via the twist-on/off quick attachment couplings. Furthermore, the solar panels couple to the top housings and are pivotable between stowed positions in which the panels lay flush with the top housings and extended positions in which the panels extend at an angle from the top housings. Moreover, the solar panels are in electrical communication with the fans. The locks operatively couple with the bottom bases and the top housings and, when in their locked positions, lock the twist-on, quick attachment couplings in their coupled positions. The biasing members operatively couple with the locks and urge the locks toward their coupled positions.

Still further, various ventilation systems according to embodiments of the present invention provide bases (defining flashing portions) and housings which together define, respectively, first and second halves of quick attachment couplings. The quick attachment couplings allow the housings to be releasably coupled to the bases. In some embodiments, exemplary ventilation systems further comprise solar panels coupled to the housings which are pivotable between stowed positions whereby such panels lay flush with the housings and elevated positions whereby the panels extend from the top of the housing.

If desired, the quick attachment couplings according to exemplary embodiments of the present invention can be twist-on (twist-off) quick attachment couplings. Such exemplary ventilation systems can include locks operatively coupled to the bases and, which when in locked positions, can lock the twist-on, quick attachment couplings in coupled positions. Furthermore, biasing members can operatively couple with the locks and urge the locks toward their locked positions. Some exemplary ventilation systems may include risers that can be adapted to releasable couple between the bases and the housings. In some exemplary embodiments, the flashing portions can be adapted to be mounted on pitched roofs, and the exemplary ventilation systems can include fans contained in the housings. In addition, or in the alternative, exemplary ventilation systems according to embodiments of the present invention may further include electrical connections adapted to receive 120 VAC (volts alternating current).

Some exemplary ventilation systems according to embodiments of the present invention may possess bases and housings which define quick attachment couplings by which the fan housings are releasably coupled to the bases. In the alternative, or in addition, exemplary bases according to embodiments of the present invention may define riser portions extending from the flashings and further defining the quick attachment couplings. The quick attachment couplings can be twist-on quick attachment couplings. Moreover, the quick attachment couplings can be locked and can be biased toward their locked positions.

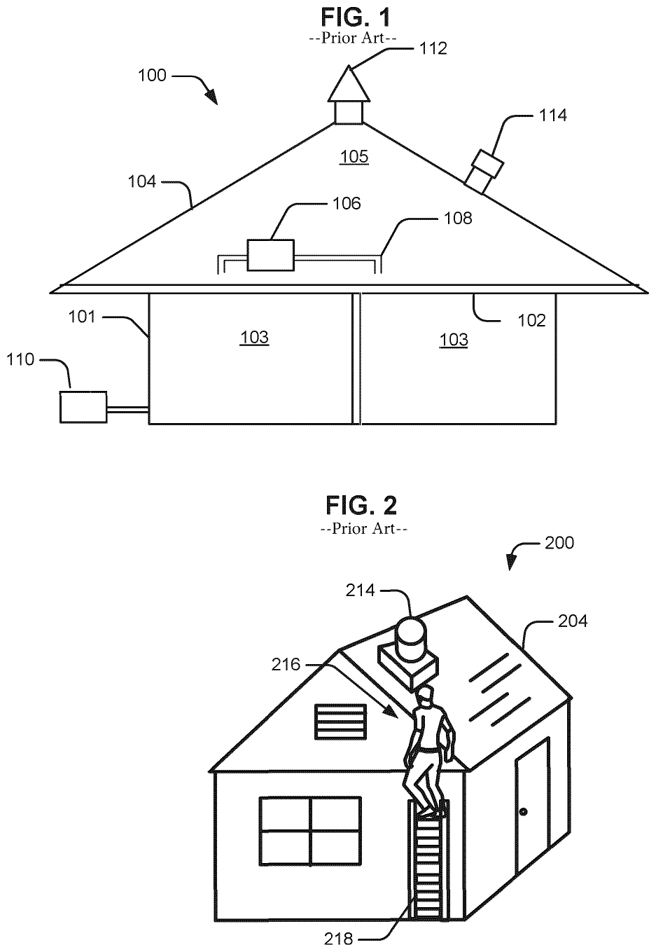

Turning to FIG. 1, FIG. 1 illustrates a building. More particularly, FIG. 1 illustrates a building 100, walls 101, a ceiling 102, air-conditioned spaces 103, a roof 104, a crawl way 105, HVAC (heating, ventilation, and air-conditioning) equipment 106, ducts 108, an air conditioner (evaporator) 110, a roof vent 112, and an roof-mounted fan system 114. The building 100 could be a residential building (as shown), a commercial building, an industrial building, etc. The building 100 exists in a region in which the sun and other heat sources create a heat load on the building 100. It also exists in an area where neighboring property owners might wish to maintain the aesthetic appearance of the neighborhood. Thus, the owner of the building 100 might wish to manage the heat load of the building 100 while not adversely affecting the aesthetic qualities of the building 100, the neighborhood, etc.

The building 100 also includes a number of walls 101 as well as or, in the alternative to, other structures. Typically, these structures define one or more of the “air-conditioned” spaces 103 and one or more of the crawlways 105. The air-conditioned spaces 103 are said to be “air-conditioned” in the sense that the condition of the air therein might be maintained more or less at some given state and, more specifically, at some desired temperature. Yet the external heat load (from the sun and/or other sources) and, potentially, internal heat loads (for instance, from lighting, electrical/mechanical equipment, occupants, etc.) can affect the temperature of those air-conditioned spaces 103. In many cases, the crawl way 105 (or attic) is included in the design of the building 100 to provide a degree of separation between the air-conditioned spaces 103 and the external environment (and its heat loads). Yet, that crawlway 105 itself can become warm thereby exposing the air-conditioned spaces 103 to heat flux from the crawl way 105 itself and/or reduce the amount of heat which would otherwise escape from the air-conditioned spaces 103 through that space.

Moreover, many building designers, owners, maintenance personnel, etc. are known to place various pieces of equipment in these crawl ways 105. For instance, building designers frequently locate HVAC equipment 106 and associated ducts 108 in these crawl ways 105. Some HVAC equipment 106, of course, represent sources of heat themselves. The ducts 108 often convey air-conditioned air and, even if insulated, allow that air-conditioned air to absorb heat from the air in the crawl way 105. Thus, heat from the HVAC equipment 106 and other heat sources can be conveyed into the air-conditioned spaces 103 via the ducts 108.

The roof 104 along with the ceiling 102 defines the crawl way 105 and tends to trap heat in that crawl way 105. Indeed, warm (or even hot) air in the crawl way 105 can rise to the crown or apex of the roof 104 where it becomes trapped unless vented. As a result, a temperature gradient can exist as sensed at various heights in the crawl way 105 with the hottest air frequently being found near the apex of the roof 104.

In many situations, users might place a roof vent 112 on the roof 104 to vent the crawl way 105. If placed near the apex of the roof 104, the roof vent 112 therefore allows the warmer air in the crawlway 105 to rise through itself and therefore escape from the crawl way 105. However, such passive roof vents 112 rely on natural convection to drive the flow of the warm air and might not therefore be that effective in managing the heat load(s) affecting the crawl way 105 (and/or the air-conditioned spaces 103). Indeed, natural convection typically does not happen in a substantial manner until the crawl way 105 temperature reaches about 136 degrees F. Thus, some users include a roof-mounted fan system 114 on the roof 104 to actively ventilate the crawl way 105.

Such active ventilation equipment such as a roof-mounted fan system 214, though comes with certain drawbacks. For one thing, heretofore-available roof-mounted fan systems 114 are bulky, awkward, and heavy and therefore difficult to install as FIGS. 2-4 illustrate. More particularly, FIG. 2 illustrates a user installing a roof-mounted fan system 214 on a building 200. FIG. 2 also illustrates a roof 204, a user 216, and a ladder 218. As illustrated, the user 216 is installing the roof-mounted fan system 214 near the apex of an angled roof 204. Indeed, the user 216 has managed to carry the bulky roof-mounted fan system 214 up the ladder 218 at something of a risk of dropping the fan system and/or falling off the ladder 218 (or otherwise damaging the fan system and/or injuring him/her self). Moreover, having managed to carry the roof-mounted fan system 214 aloft, the user 216 must now perch at the top of the ladder 218, maneuver it into place, and mount it to the roof. 204. To do so, the user 216 must often reach around the roof-mounted fan system 214 to its opposite side which the user 216 cannot see, much less reach conveniently.

Further still, the user 216 must then access the under side of the roof-mounted fan system 214 from the attic of the building 200 to provide power to the roof-mounted fan system 214. That power might or might not be available at the location of the roof-mounted fan system 214. Thus, the user 216 might need to run wires, a conduit, etc. to the roof-mounted fan system 214 as well as wire it to a thermostat if thermostatic control of the roof-mounted fan system 214 is desired. In the alternative, the user 216 might have purchased a roof-mounted fan system 214 with an add-ons solar panel. However, solar panels are often considered eyesores and add-on solar panels typically aggravate this condition. Indeed, some homeowners associations (HOA), municipalities, etc. place restrictions on the use of solar panels on roofs 204 (and/or other locations).

Further still, with heretofore-available roof-mounted fan systems, the solar panels are simply added to the fan systems with little or no attempt to incorporate the solar panels into the aesthetic design of these fan systems. Thus, these solar panels detract from the aesthetic features of these heretofore-available roof-mounted fan systems 214. Moreover, the solar panels (on installed roof-mounted fan systems 214) might or might not point toward the sun thereby reducing their efficiency to a point at which they might not be able to adequately drive the fan systems.

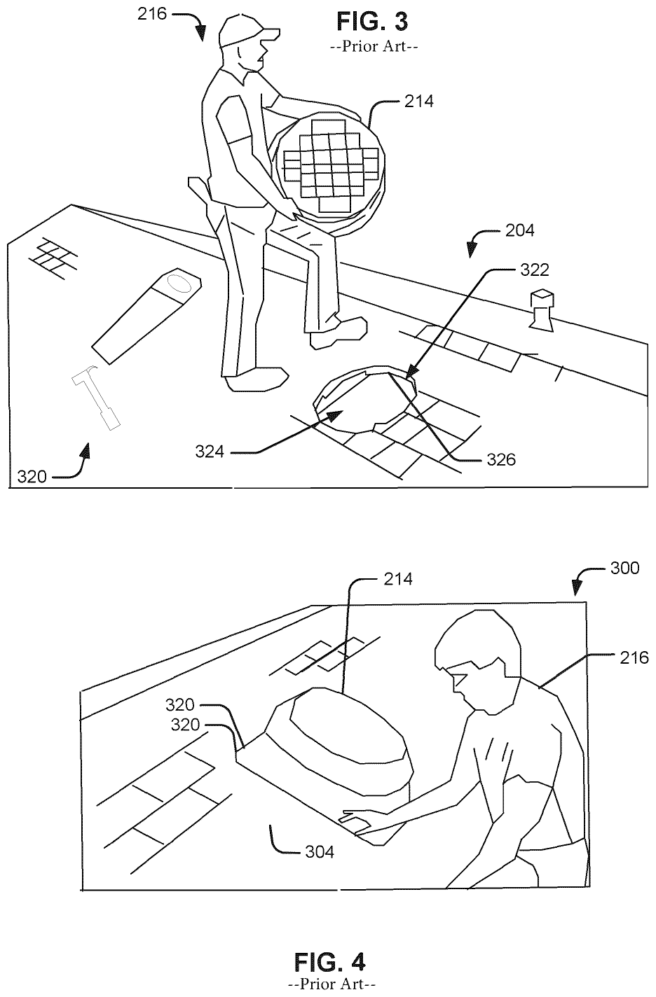

FIG. 3 further illustrates a user installing a roof-mounted fan system 214. More particularly, FIG. 3 illustrates a flashing 320, a penetration 322, rafters 324, a roof deck 326, roofing materials 328, and tools 330. The user, of course, could be a worker, home (or building) owner, a maintenance technician (electrician or mechanic perhaps), or other user. Nonetheless, the roof-mounted fan system 214 is often so bulky that the user 216 can barely get their arms around it and must carry it in a position whereby its center of gravity is relatively distant from the user 216. Heretofore-available roof-mounted fan systems 214 also happen to be heavy, which makes carrying and maneuvering these roof-mounted fan systems 214 that much more difficult. More specifically, the user 216 must (despite these challenges) maneuver the roof-mounted fan system 214 over the penetration 322, center it, and secure it to the roof deck 326.

As those skilled in the art will appreciate, roof deck 326 rests on numerous rafters 324. Typically, the rafters 324 are long 2″×4″ boards which (laid in an appropriate manner) can support the weight of the roof deck 326, material (for instance, snow, water, etc.) on it, users 216, wind loads (with appropriate bracing), etc. Typically, the rafters 324 are spaced apart by 24 inches and/or correspond (in spacing) to the typical 4×8 foot size of the plywood panels that make up the roof deck 326. Other rafter 324 spacing dimensions are possible though. Moreover, the rafters 324 and/or roof deck 326 are typically pitched at angles corresponding to a rise/fall of 3 inches per foot although buildings having different roof pitches (for instance, 7 and 10 roof pitches) are certainly in existence and within the scope of the current disclosure. Indeed, some roofs 304 are flat (or have pitches much less than 3 inches per foot) and might have rafters 324 with increased dimensions to better bear the loads associated with such roof pitches.

The roof deck 326 itself is typically made of 4×8 foot sheets of plywood on which the roofing materials 328 are secured. In many cases, those roofing materials 328 include an underlying layer(s) of tarpaper and one or more layers of shingles. The tarpaper serves to waterproof the roof 304 so that rain, snowmelt, and/or other forms of water cannot penetrate the roof 304 and/or seep into the building. The tarpaper typically rests on the plywood of the roof deck 326 with the shingles overlying it. The shingles are thicker and more durable than the tarpaper and primarily serve to protect the tarpaper from damage by the elements, workers, objects falling (or being blown) onto the roof 304, etc. Shingles are typically applied to the roof 304 in overlapping rows with the lower ends of shingles in higher rows resting on the upper ends of the shingles in lower rows. Moreover, shingles in adjacent rows are positioned such that the gaps between shingles of a given row do not align with gaps in adjacent rows. Thus, these features tend to waterproof the roof 304 when taken together so long as no penetration through the roofing materials 328 occurs. Note that roofs with ceramic tiles, concrete tiles, sheet metal (corrugated or otherwise), wooden shakes, etc. are within the scope of the current disclosure.

With continuing reference to FIG. 3, installing a roof-mounted fan system 214 on a roof 204 typically requires that a relatively large penetration 322 be made in the roof 204 and roofing materials 328. Indeed, to install a roof-mounted fan system 214 most users 216 would enter the crawl way 105 beneath the roof 204 and select a location (usually near the roof apex) for the fan system. They would then find a space between two rafters 324 for the fan system. If the space is large enough to accommodate the fan system, the user 216 often drills a hole (hammers a nail, etc.) through the roof deck 326 at the desired location for the center of the fan system. They then climb down out of the crawl way 105, exit the building, and climb to the top of the roof 204 where they would locate the previously drilled hole. Using a compass of sorts, the user 216 then typically marks the location of the intended periphery of the penetration 322 in accordance with the diameter of an opening in the fan system. Then, using an appropriate saw or other tool(s), the user 216 cuts through the shingles, tarpaper, other roofing materials 328, and the roof deck 326 to form the penetration 322.

FIG. 4 still further illustrates a user installing a roof-mounted fan system. Once the penetration 322 is prepared, the user 216 then maneuvers the bulky roof-mounted fan system 214 into position roughly over the penetration 322. But, provision must usually be made to prevent water from entering the building 200 through the penetration 322. For such reasons, the roof-mounted fan system 214 includes the flashing 220 around its lower end that, if properly installed (each time a roof-mounted fan system 214 is installed, replaced, etc.), will exclude such water. Accordingly, the user 216 must lift the roofing material 328 near one of the sides of the penetration 322 and apply caulk (or some other sealant) to the roof deck 326 before sliding the flashing 320 underneath the temporarily lifted roofing material 328. The user 216 must repeat these actions for every side of the penetration 322/fan system.

Moreover, the user 216 must do so without damaging the remaining roofing material 328; while not being able to see around the fan system; and by maneuvering that bulky, awkward, roof-mounted fan system 214 to make even small positional adjustments. With roof-mounted fan systems 214 heretofore-available, it is quite likely that the installation will fail in at least some of these regards thereby allowing water to penetrate the building 200 (not to mention perhaps leading to an installation with an un workman-like appearance). The user 216 can then tamp the roofing material 328 down over the flashing 320 of the fan system and hope that wind does not “get under it” and remove it from the roof 204 thereby leading to yet more damage to the building. Of course, the user 216 typically also has to reenter the crawl way 105 (from the other side of the roof 204) and connect power to the roof-mounted fan system 214. Accordingly, the installation of each heretofore-available fan systems 214 tends to be time-consuming, expensive, and prone to failures, errors, omissions, etc.

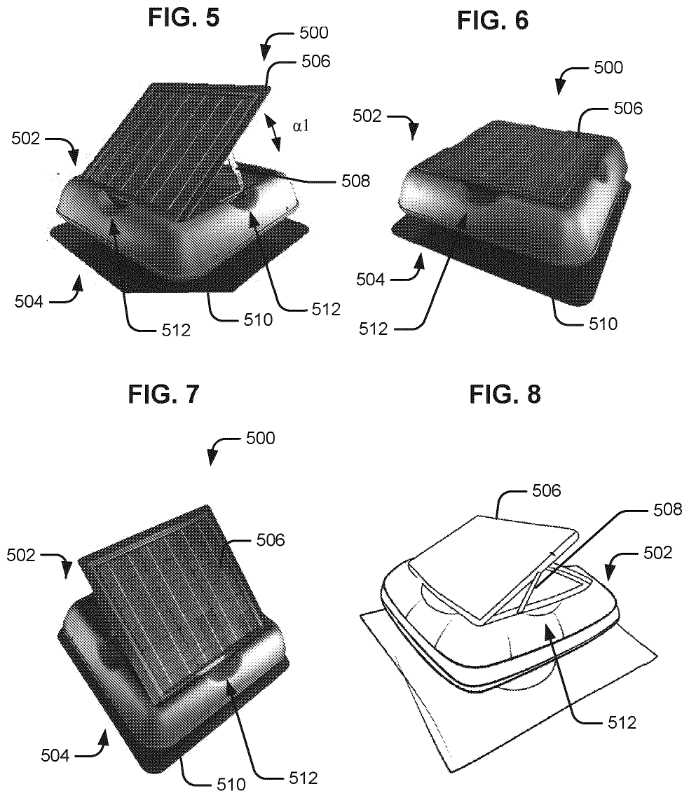

FIGS. 5-8 illustrate a two-piece fan system with a solar panel in various positions. The two-piece fan system 500 of the current embodiment comprises at least two-pieces: a fan housing 502 and a base 504. The two-piece fan system 500 of the current embodiment also includes a solar panel 506 and adjustable bracket 508 as well as flashing 510. The fan housing 502 contains a fan, motor, and associated bearings, races, etc. and airflow guides, vanes, etc. It therefore contains the active mechanical components of the two-piece fan system 500 of the current embodiment. Moreover, the solar panel 506 and adjustable bracket 508 operationally couple with the fan housing 502. The fan housing 502, additionally, can include wiring to electrically connect the solar panel 506 to the fan and perhaps some controls (for instance, thermostats, thermal cut-off switches, remote control circuitry, etc.) for the fan motor.

Mechanically, the adjustable bracket 508 operatively couples the solar panel 506 to the fan housing 502. In some embodiments, the adjustable bracket 508 includes one or more “stops,” at which it can be locked, to position the solar panel 506 in a corresponding number of positions relative to the fan housing 502. Thus, the solar panel 506 pivots about the fan housing 502 through an angle a1 between its stowed position (see FIG. 6) and its extended position (FIG. 5) and through the various intermediate stop-related positions. These positions allow a user 216 to more accurately point the solar panel 506 at the sun or other light source as might be desired. Indeed, by orienting the fan housing 502 and using the adjustable stops, users 214 can orient the solar panel 506 to point generally toward the sun in many if not all locations including many north-facing roofs. A range of angle a1 from 0 degrees in the stowed position to about 45 degrees has been found to be satisfactory for such purposes.

In the stowed position, though, the solar panel 506 rests in the fan housing 502 with its surface flush with the nominally upper surface of the fan housing 502. In this position, the adjustable brackets fold into the housing thereby allowing the solar panel 506 to appear to be embedded in the housing and/or flush with its surface.

The fan housing 502 also defines one or more vents/drains 512. These vents/drains 512 provide a flow path around the solar panel 506 when the solar panel 506 is in its stowed position, flush with (or embedded in) the fan housing 502. In this way, even when the solar panel 506 is stowed some air can flow beneath it and cool it. These vents/drains 512 can also serve as finger holds for users 214 to reach underneath the solar panel 506 and lift it to one of its non-stowed positions. They also allow for water to drain from under the solar panel 506.

Furthermore, the fan housing 502 of the current embodiment defines a low profile and has an overall oblong, rounded shape. The vents/drains contribute to this low profile (a height less than about 7″ in some embodiments and less than about 3″ in the current embodiment), rounded appearance in that they are formed integrally with the (nominally) upper portions of the sides of the fan housing 502. The vents/drains 512 are also rounded at least in part for aesthetic considerations. Note that the fan housing can be made of some paintable material such as ABS (Acrylonitrile butadiene styrene) plastic so that the two-piece fan system 214 can be painted in accordance with user desires, local aesthetic rules, deed restrictions, ordinances, etc.

Note that FIGS. 5-7 illustrate the two pieces (the fan housing 502 and the base 504) of the two-piece fan system 500 according to exemplary embodiments being coupled together. FIG. 8, in contrast, illustrates the fan housing 502 separate and apart from any base 504. Indeed, the base 504 can be installed on various roofs 204 with the fan housings 502 being installed at some different time and/or interchanged with one another. In accordance with the current embodiment, therefore, the fan housings 502 can be interchanged with one another, removed, replaced, etc. without disturbing the roof 204, the roof deck 326, the roofing materials 328, etc. and without tools 330 and the like. Furthermore, once a base 504 of suitable size is installed on a roof 204, the user can “install” a “fan” by merely carrying a fan housing 502 to the already installed base 504, placing it on the base 504, and removably coupling that fan housing 502 to the base 502. In the current scenario, the user 216 need not carry or maneuver the (bulk of the) base 504, flashing 510, etc. Thus, the current embodiment facilitates the installation (and/or replacement, maintenance, etc.) of fan systems while eliminating much of the work, expense, and inconvenience associated therewith.

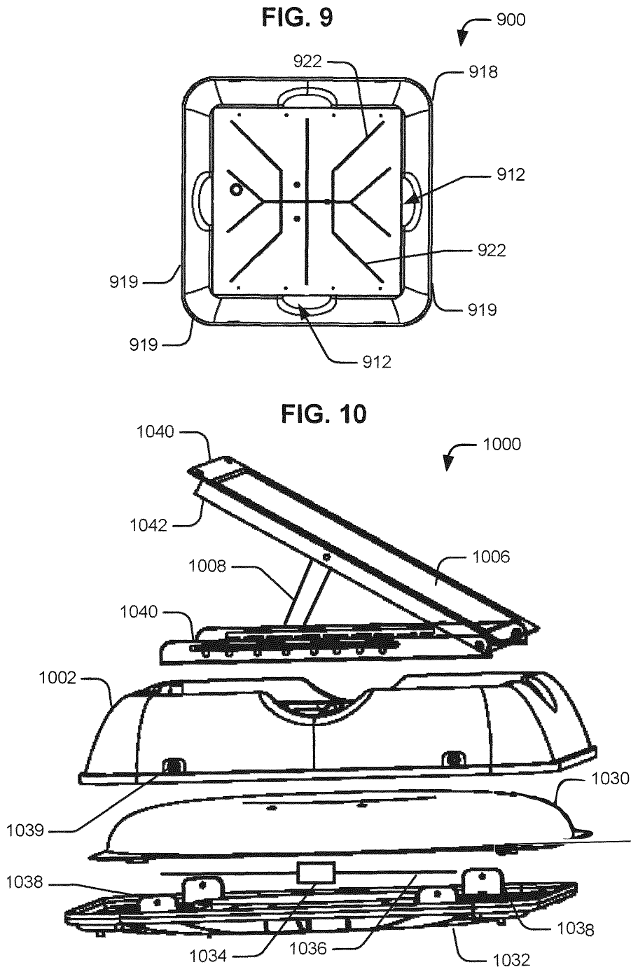

FIG. 9 illustrates a top plan view of a housing of a two-piece ventilation system. More particularly, FIG. 9 illustrates a fan housing 900, vents/drains 912, a body 918, sides 919, a recess 920, and ribs 922. As alluded to elsewhere herein, the body 918 of the fan housing 900 contains a fan, its blades, etc. and defines the vent/drains 912. Additionally, in the current embodiment, the body 918 also defines the recess 920 into which the solar panel 506 fits and/or appears to be embedded (when stowed) in the housing. Those solar panels 506 can be made from a variety of materials, including but not limited to polycrystalline, multicrystaline, monocrystaline, etc. without departing from the scope of the current disclosure. In some embodiments, the body 918 also defines one or more of the ribs 922 on its nominally upper surface in the recess 920. These ribs 922 can provide a degree of rigidity to that surface and can allow some space between it and the solar panel 506 (when stowed). This space can allow the solar panel 506 to breath and thus remain relatively cool during operation (and during non-operation). This space also allows the area under/behind the solar panel 506 to drain should moisture be present.

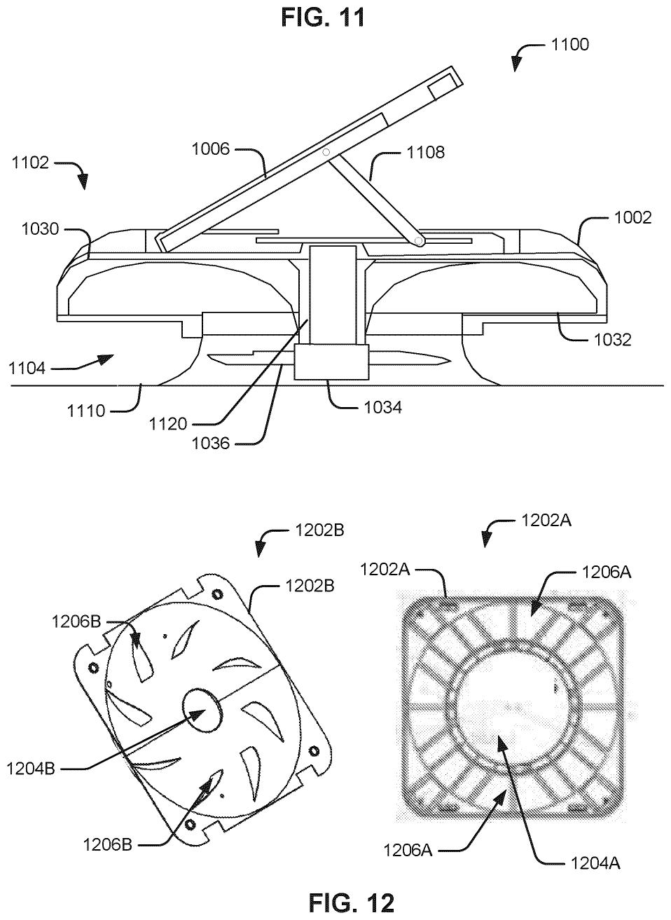

FIG. 10 further illustrates an exploded view of a housing for a two-piece fan system. More particularly, FIG. 10 illustrates the fan system 1000 and its housing 1002, solar panel 1006, adjustable brackets 1008, cowling 1030, closure 1032, fan motor 1034, fan blades 1036, bosses 1038, fastener holes 1039, and rails/locks 1040. Generally, the fan motor and blades 1034 and 1036 (as a unit) respectively fit inside the cowling 1030 which fits inside the housing 1002. The closure 1032 along with the housing 1002 (and appropriate fasteners) closes the fan 1000 as an assembly and clamps it together. As is disclosed further with regard to FIG. 11, the closure 1032 defines at least one aperture that allows the fan to draw air into itself while the cowling 1030 is shaped and dimensioned to smoothly turn that flowing air with relatively low head loss back toward the closure 1032 in a relatively small axial distance (less than 4-7″ in many embodiments). In some embodiments, the cowling 1030 eliminates air pockets and associated energy wasting eddy currents therein. The cowling 1030 can also include guide vanes for the air if desired. The closure 1032 also defines at least one aperture which allows the (turned) airflow to exit the fan system 1000. Thus, the air flows upward through the closure 1032, through the fan blades 1036 (which drive the airflow at least in part), through the tum guided by the cowling 1030, and then back out through the closure 1032.

As further illustrated by FIG. 10, the closure 1032 defines one or more bosses 1038 with holes adapted to receive closure fasteners. Those holes align with the fastener holes 1039 on the housing 1002. Thus, with the cowling 1030 and fan blades 1036 and fan motor 1034 in the housing 1002, fasteners can be used to assemble the fan system 1000 into a separate, stand-alone unit.

FIG. 10 also shows that the solar panel 1006 can include or be operationally coupled to the adjustable brackets 1008. The adjustable bracket 1008 can cooperate with the corresponding rails/locks 1040 to allow users to adjust the position of the solar panel 1006 with respect to the housing 1002. The rail/locks 1040 can also, or in the alternative, cooperate with the adjustable brackets 1008 to lock the solar panel 1006 in one or more of those positions.

In the current embodiment, a frame 1041 surrounds, holds, and/or supports the solar panel 1006. While the frame 1041 of the current embodiment can provide structural support to the solar panel, another function it provides is to shield the solar panel 1006 from the environment, physical damage/abuse, and form being seen. Thus, the frame 1041 aids in preserving the aesthetic appearance of the fan system and/or its housings. Furthermore, the frame 1041 can be (spray) painted in accordance with user desires, homeowner association rules, ordinances, etc. A backing 1042 can also be applied to the side of the solar panel 1006 closest to the body of the two-piece fan system 1000. It too can be painted and/or it can be black so as to shield the backside of the solar panel from view and to aid in the aesthetic features of the fan system.

FIG. 11 illustrates a cross-sectional view of a two-piece fan system. More particularly it shows the fan motor 1034 and fan blades 1036 assembled within the cowling 1030 which is itself within the housing 1002. Further, FIG. 11 illustrates the closure 1032 fastened to the housing (via fasteners in the fastener holes 1039 and bosses 1038) and clamping the fan assembly 1102 together. FIG. 11 also shows the two-piece fan system 1100 with the solar panel 1006 operationally coupled to the fan assembly 1102 via the adjustable bracket 1008. Moreover, FIG. 11 illustrates the base 1104 includes flashing 1110, where the base 1104 is releasably attached to the fan assembly 1102. Note that the fan assembly 1102 and base 1104 can be separated from one another with, if desired, the base 1104 being coupled to and/or being installed on a roof or other structure. In the embodiment illustrated by FIG. 11, furthermore, the various components of the two-piece fan system 1100 are coaxial with one another although they need not be for the practice of the current embodiment.

Moreover, FIG. 11 illustrates a motor bracket 1120. In the current embodiment, the motor bracket 1120 defines various attachment points corresponding to various motors. Thus, it can allow for the interchange of motors as might be desired. The motor bracket 1120 can also provide physical protection to the motor and/or its coupling to the fan blades against mechanical damage from, for instance, animals that might intrude into the fan housing. This feature helps keep the fan blades in balance, running smoothly, and without undue noise.

FIG. 12 illustrates a top plan view of a pair of closures for two-piece fan systems. Both closures 1200A and B include a generally planar body 1202A and B shaped and dimensioned to fit into the open end of various housings 1002. The closures 1200A and B also define, respectively, central apertures 1204A and B through which the various fans (or fan blades 1136) can draw air. The closures 1200A and B also defined a plurality of apertures 1206A and B through which air, driven by the fan blades 1136, can flow from the fans. In some embodiments, the closures 1200 can include a screen over one or more of the apertures to, for instance, keep insects, birds, rodents, other animals, debris, water, etc. out of the fans.

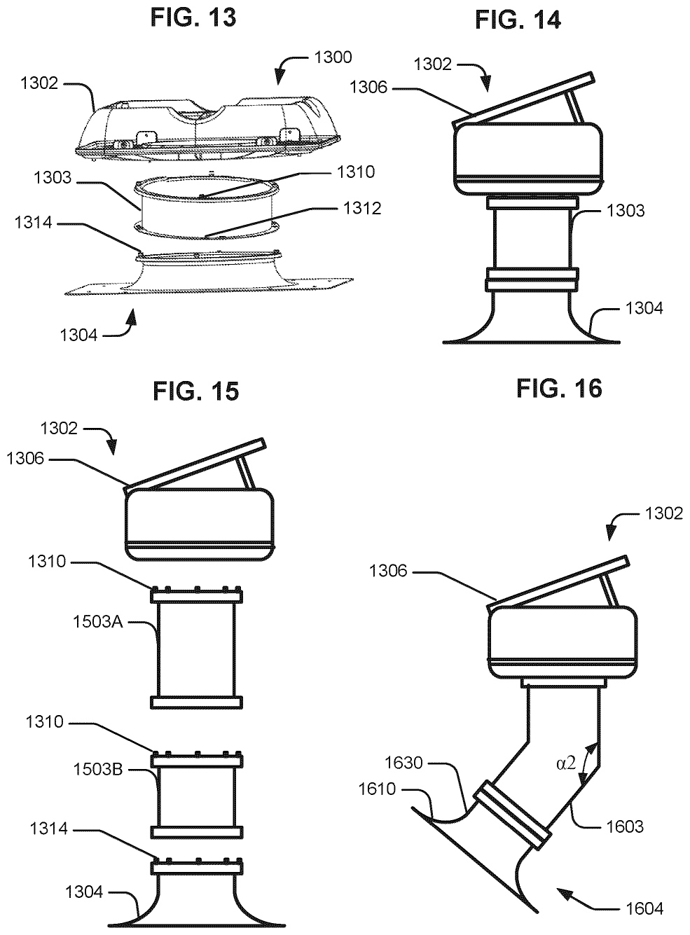

FIG. 13 illustrates an exploded view of a two-piece fan system. More particularly, FIG. 13 illustrates a two-piece fan system 1300 including a fan assembly 1302, a riser 1303, and a base 1304. The fan assembly 1302, of the current embodiment, includes a fan (a motor and a set of blades in this embodiment), a housing, and a closure. In FIG. 13 a solar panel is not shown although the two-piece fan system 1300 could include a solar panel with or without adjustable brackets. The base 1304 includes a flashing and is shaped and dimensioned to be attached to a roof, roof curb, or other structure and to lend the two-piece fan system 1300 stability when installed.

In the current embodiment, the two-piece fan system 1300 also includes the riser 1303 which could be considered as a part of the base 1304 or the fan assembly 1302 or even a third component/assembly of the “two-piece” fan system 1300. The riser 1303 is shaped and dimensioned to reside between the fan assembly 1302 and the base 1304. While it can be coaxial with the other pieces of the two-piece fan system 1300, it does add height to the two-piece fan system 1300. In other words, the riser 1303 (or extender) spaces the fan assembly 1302 apart from the roof or other structure to which the two-piece fan system 1300 might be mounted. Thus, should water, snow, ice, debris, etc. accumulate around the base 1304, the operation of the fan system can remain relatively un-affected. But, the extension need not be in a vertical direction to practice the current embodiment.

Moreover, because the open end of the riser 1303 (when installed on a base 1304) might be clear of such debris, a two-piece fan system 1300 (or rather a fan assembly 1302 of a two-piece fan system 1300) can be installed even in the presence of that debris in many cases. Indeed, since 5-6″ of snow is often considered to be good insulation, users can install fan assemblies on risers with lengths of about 6″ without disturbing that snow. For roofs covered with sod, dirt, grass, sand, gravel, etc. two-piece fan systems (with risers and/or riser portions) of embodiments provide similar features.

FIG. 13 also illustrates that risers 1303 of the current embodiment can include two sets of quick attachment coupling halves, male half 1310 and female half 1312. These coupling halves 1310 and 1312 can be shaped and dimensioned to mate with corresponding coupling male halves 1314 on the bases 1304 and fan assemblies 1302. Also, if desired, one set of the coupling halves 1310 or 1312 can be adapted to mate with corresponding coupling halves on the fan assemblies 1302 while the other set (on the riser 1303) can be adapted to mate with the coupling halves on the bases 1304. In such manners, risers 1303 can be stacked one atop another to extend the fan assemblies 1302 to lengths determined by the dimensions of the selected risers 1303 and/or their numbers. If desired, the various coupling halves 1310, 1312, and/or 1314 can be adapted to pull the various components/assemblies 1302, 1303, and/or 1304 into close fitting and/or weather proof alignment with one another. Additionally, or in the alternative, these components 1302, 1303, and/or 1304 can be adapted to be used with gaskets, O-rings, sealants, and/or other weatherproofing techniques to prevent water intrusion, air infiltration, etc. through the joints there between.

FIG. 14 illustrates such a two-piece fan system installed on a roof with a riser 1303 installed between the fan assembly 1302 and the base 1304. FIG. 15 illustrates an exploded view of a two-piece fan system and multiple risers 1503A and 1503B installed therewith. FIG. 15 also shows that such multi-riser two-piece fan systems 1500 can include a solar panel and adjustable brackets) coupled thereto. FIG. 16 illustrates a two-piece fan system with a riser installed on a roof. In the embodiment illustrated in FIG. 16, the riser 1603 is configured to tum through an angle a2. That angle a2 could correspond to one of the common angles at which roofs are pitched although it need not do so. In such cases though, the use of the angled riser 1603 can serve to turn the orientation of the two-piece fan system (or fan assembly 1602) to some desired direction such as vertical (as shown). Moreover, in some embodiments, one or more risers can be used in combination/conjunction with other risers whether straight, angled, or otherwise. FIG. 16 also illustrates, in at least some sense, that the base 1604 can be considered an assembly. For instance, the base 1604 could define or comprise a flashing portion 1610 coupled to a riser portion 1630. The riser portion 1630 could further define, comprise, be coupled to, etc. quick attachment couplings.

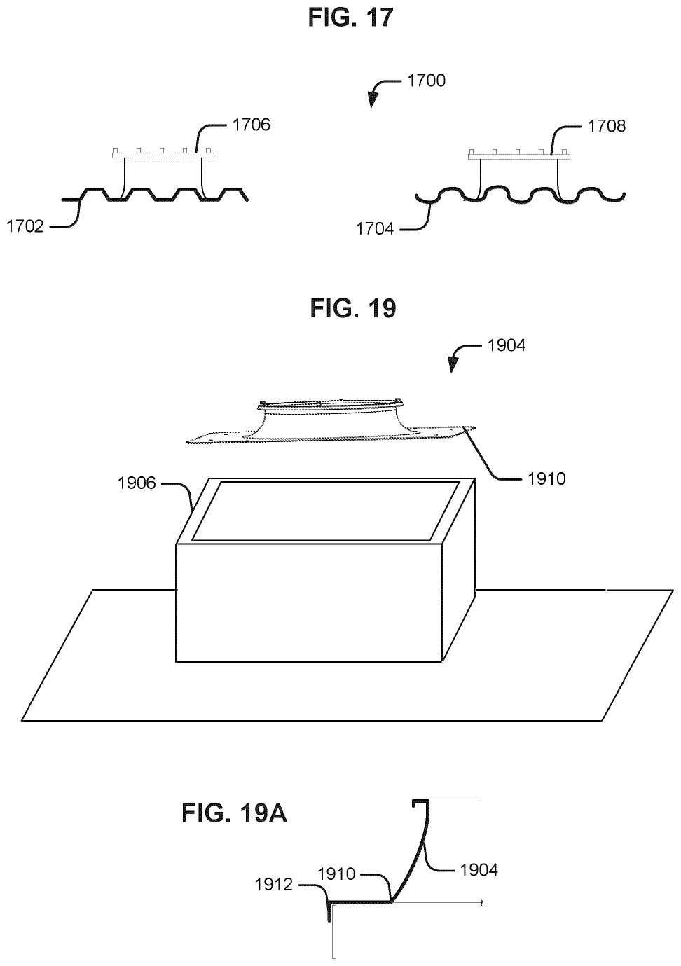

FIG. 17 illustrates a corrugated roof and bases for two-piece fan systems. More particularly, the corrugated roof 1700 of the current embodiment includes a portion 1702 which appears trapezoidal when viewed in cross-section and a portion 1704 which appears sinusoidal in cross-section. The corrugated roof 1700 also includes two bases 1706 and 1708 which, respectively define flashings with corresponding corrugated trapezoidal and sinusoidal cross-sections. Thus, embodiments allow two-piece fan systems to be installed on, mounted on, attached to, etc. corrugated roofs without altering the corresponding risers and/or fan assemblies.

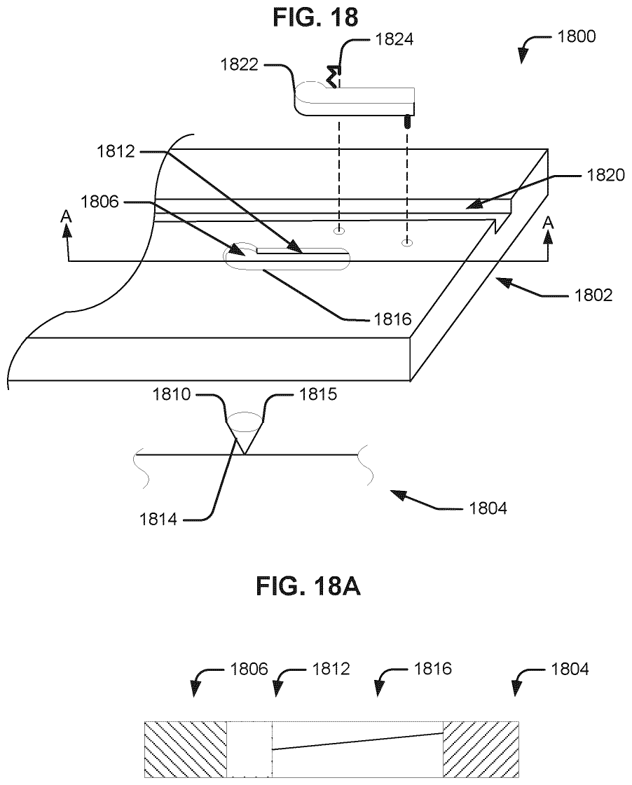

FIG. 18 illustrates a quick attachment coupling for exemplary ventilation systems according to embodiments of the present invention and FIG. 18A illustrates a cross-sectional view a first half of the quick attachment coupling as seen along line AA of the first half in FIG. 18. More particularly, FIGS. 18 and 18A illustrate that the quick attachment coupling 1800 of the current embodiment defines a male half 1804 and a female half 1802 with the two halves being designed to releasably engage each other and to releasably couple assemblies of two-piece fan systems together. Thus, these male and female halves 1804 and 1802, respectively, can be shaped and dimensioned to withstand wind (and/or other) loads likely to be imposed on various two-piece fan systems with and/or without risers. Additionally, these coupling halves 1802 and 1804 can be shaped and dimensioned to draw the fan assemblies together with sufficient force to form a seal there between in the presence and/or absence of gaskets, O-rings, and/or other sealing structures/devices.

With continuing reference to FIG. 18, the female half 1802 of the current embodiment can define a relatively large aperture 1806 which can accept a corresponding and/or relatively large portion 1810 of the male half 1804. These structures allow the halves 1802 and 1804 to engage each other and disengage from each other. The female half 1802 can also defines a narrow aperture 1812 which can accept a corresponding small portion 1814 of the male half 1804. Thus, once the halves 1802 and 1804 are engaged with each other, the narrow portion 1814 of the male half 1804 can be slid along the narrow aperture 1812 of the female half 1802 so that the halves 1802 and 1804 can remain engaged with each other despite axial forces imposed on their corresponding fan assemblies. The halves 1802 and 1804 can also remain in sliding engagement with one another (at least for some distance) in such circumstances even if some torsional forces attempt to rotate one fan assembly relative to the other in the current embodiment. Nonetheless, such features allow assemblies of embodiments to be releasably coupled to one another with a twist of one assembly relative to another.

FIG. 18 illustrates that the male and female halves 1804 and 1802, respectively, define guide surfaces 1815 and 1816. These guide surfaces 1815 and 1816 can be shaped and dimensioned such that, as the coupling halves 1802 and 1804 slide relative to one another, the guide surfaces 1815 and 1816 urge the halves 1802 and 1804 toward one another (axially) thereby drawing the respective assemblies into abutting relationship. Moreover, the guide surfaces 1815 and 1816 can be configured to impart enough force on the respective fan assemblies to form a seal there between. That seal can be made, enhanced, etc. with a gasket, O-ring, etc. which might/might not be positioned in a groove 1820 in the surface of one fan assembly or another.

Further still, in some embodiments, the quick attachment coupling 1800 includes a latch 1822. The latch 1822 can be positioned on the fan assembly with the female half 1802 to releasably capture the male half 1804 as the halves engage each other. In some embodiments, the latch 1822 (and the coupling halves 1802 and 1804) is configured and positioned to be released manually. In addition, or in the alternative, the latch 1822 can be biased into a position (for instance a locked/latched position) by a biasing members such as a spring 1824.

FIG. 19 illustrates a base for a two-piece fan system and FIG. 19A illustrates a cross-sectional of the base 1904 of FIG. 19. The base 1904 of the current embodiment mates with rectangular roof curbs 1906 so that two-piece fan systems can be mounted thereon in accordance with embodiments. Instead of a flashing, the base 1904 defines an adaptor 1910 shaped and dimensioned to mate with the roof curb 1906 and to seal thereto. Quick attachment couplings, fasteners, etc. can be used to secure the adaptor 1910 (and base 1904) to the roof curb 1906. Moreover, the adaptor 1910 can further define a lip 1912 which can aid in registering the base 1904 with the roof curb 1906. The lip 1912 can also assist in sealing the joint between the base 1904 and the roof curb 1906 and can be used as a location for quick attachment couplings, fasteners, etc. for securing the base 1904 to the roof curb 1906.

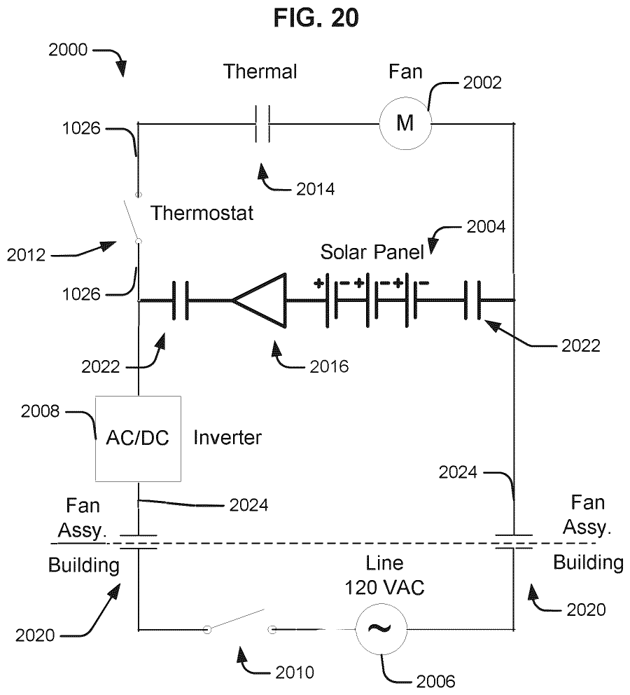

FIG. 20 illustrates a schematic of an exemplary circuit associated with some exemplary ventilation systems according to embodiments of the present invention. More particularly, FIG. 20 illustrates a circuit 2000 which includes a fan motor 2002, a solar panel (or solar cells) 2004, a source of (120 VAC) line power 2006, an inverter 2008, an on/off switch and/or breaker) 2010, a thermostat 2012, a thermal cutoff switch 2014, an isolator 2016, and two pairs of contacts 2020 and 2022, quick disconnects, etc. Generally, the solar panel 2004 and line power 2006 may be wired in parallel across the fan motor 2002 in the exemplary embodiment. Moreover, the contacts 2020 allow those components on the fan assembly to be connected to (and disconnected from) line power 2006 while the contacts 2022 allow the solar panel to be electrically (dis) connected to the fan motor 2002.

Of course, fan systems of embodiments could operate on only one of the solar panel 2004 or line power 2006. In such embodiments, the circuit 2000 can be simplified accordingly. Indeed, where power is only available from the solar panel 2004, the fan motor 2002 will slow down/stop as the light fades thereby allowing natural convection/breezes to ventilate the crawl way 105 during dark periods.

Nonetheless, the inverter 2008 illustrated by FIG. 20 converts the line power 2006 to DC (direct current) power compatible with the fan motor 2002 which can be selected to be driven by DC power from either/both of the solar panel 2004 and/or the inverter 2008 (and, thus, line power 2006). The isolator 2016 can be included in the circuit 2000 so as to protect the solar panel 2004 from being back-driven by that DC power. Moreover, the thermostat 2012 can determine when the fan motor 2002 runs responsive to the temperature sensed by the thermostat 2012 while on/off switch 2010 allows users to control the fan motor 2002 at least as far as line power 2006 might be involved. Of course, if desired, the fan motor 2002 can be instrumented with the thermal cutoff switch 2013 to shut it off if it should over-heat.

FIG. 20 also schematically illustrates that the on/off switch 2010 and the source of line power 2006 can be located in/on the building on which the fan system is to be mounted. Meanwhile, the remaining components illustrated by FIG. 20 can be located on the fan assembly (or if desired the base or riser) associated with the circuit 2000. A pair of wires 2024 can run through the fan assembly from the components there on toward the riser/base. These wires 1024 can be routed through the riser/base and thence to some connection point and can terminate in the contacts 2020. In some embodiments, the wires 1024 run external to the fan assembly and can be routed through the building/environment outside of the fan system, fan assembly, riser, base, etc. although they need not be so routed to practice embodiments. Another pair of wires 1026 can be routed through the fan assembly/riser/base so that the thermostat 2012 can be removably (re) located in or near the inlet of the base, riser, fan assembly.

In some embodiments, though, the those wires 1026 further comprise a 36″ (or other length) cable allowing the thermostat 2012 to be located at a location with temperatures representative of the crawl way 105. For instance, the area/strata of air near the roof apex is often warmer than the overall crawl way 105. Placing the thermostat 2012 elsewhere (for instance lower) in the crawl way 105 by using the wires 2026 can allow for control of the fan motor 2002 responsive to temperatures more representative of overall conditions in the crawl way 105.

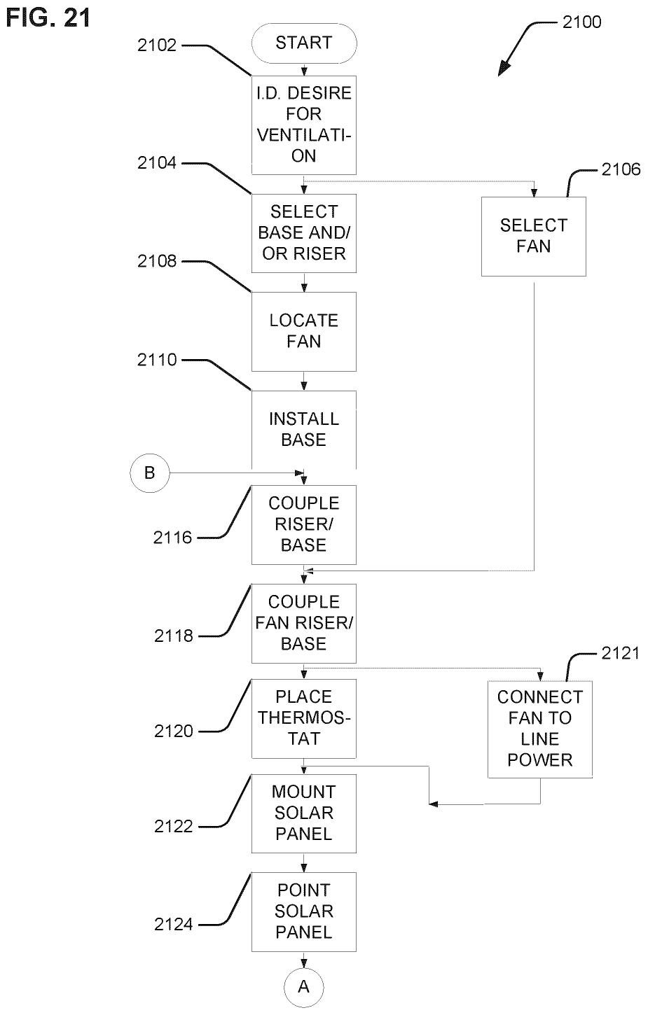

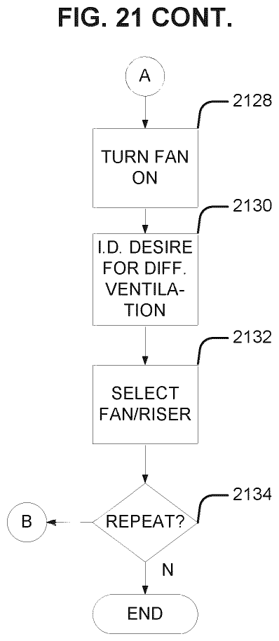

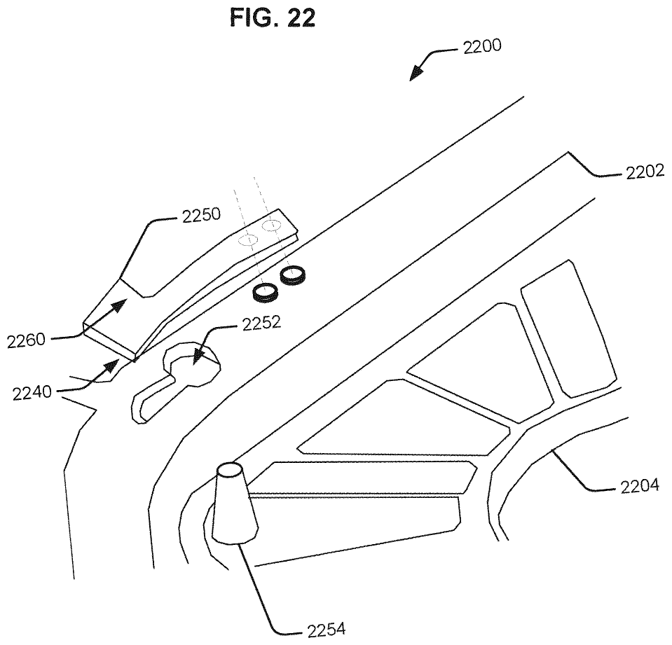

FIG. 21 illustrates a flowchart of a method related to two-piece fan systems. The method 2100 includes numerous activities such as identifying a desire for improved ventilation. Sec reference 2102. That desire might arise from a user noticing that one or more air-conditioned spaces 103 in a building 100 has been and/or has become warmer than desired. In some cases that desire might arise from a user noticing that a crawl way 105 has become susceptible to mold, mildew, etc. Of course, many circumstances could prompt a user to desire improved ventilation and, indeed, these circumstances might occur in various combinations.

With continuing reference to FIG. 21, one response to such situations is to install (or change) a fan system that ventilates the crawl way 105 of the building 100. Doing so would probably remove warm air from the crawl way 105 and allow warm air from elsewhere to rise to the crawl way 105 where it would also be removed. Such airflow would tend to cool the crawl way 105, the HVAC equipment 106 and/or ducts 108 therein as well as likely reducing the heat load(s) on the air-conditioned spaces 103 of FIG. 1.

Therefore, given the size of the building 100, its air-conditioned spaces 103, the solar insolation in the building's environment, likely weather/climate conditions, the likely occupancy/use of the building, etc. a user can select a fan assembly by size and/or type for use in ventilating the crawl way 105. With heretofore available fan systems, once a user installs the selected fan system, a change or modification to that fan system (or selection thereof) might necessitate a re-engineering/re-design of the installation-site as well as, perhaps, performing again most (if not all) of the installation procedures for the (newly) selected heretofore available fan system. Thus, with such fan systems, changing a selection and/or replacing an existing fan could be comparatively expensive. In contrast, many of these adverse consequences can be avoided with two-piece fan systems of embodiments although doing so is not necessary for the practice of embodiments.

With reference again to FIG. 21, method 2100 can continue with a user selecting various assemblies with which to build/install a two-piece fan system 1300 (FIG. 13) of embodiments. For instance, a user can select a base 1304 by its diameter (or size as pertinent to HVAC considerations), the type of roof 104 it is to be installed on, its shape (for instance, round or rectangular), etc. Moreover, the user can select the base 1304 independently of their selection of the fan assembly 1302. See reference 2104. If desired, the user can select one or more risers 1303 for use with the base 1304. These risers 1303 can be straight, angled, etc. and the user can select more than one riser 1303 if desired. Thus, the user can design a two-piece fan system 1300 while accommodating local concerns such as the possibility that rain, snow, ice, debris, etc. might accumulate on the roof 104 near the fan system 1300.

Method 2100 can continue with the user selecting a fan assembly 1302. The user can base this selection on the size of the fan desired (for instance, desired flow rate, head/pressure, energy consumption, etc.), its type (axial, centrifugal, mixed, etc.), etc. See reference 2106. Again, the user can make the selection of the fan assembly 1302 and base 1304 (and riser) more or less independently of one another provided that they are generally the same size and shape at the joint where they are to be coupled to one another.

At some point, a user can install the base 1304. Installing the base 1304 can be performed at a different time, by different users, with different tools, etc. than the installation of the fan assembly 1302 (and/or riser 1303). Thus, for instance, the installation of the base 1304 could be performed by a user(s) with mechanical/carpentry skills while installation of the fan assembly 1302 could be performed by a user with enough electronic skill to make the electrical connections and/or mechanical skills to install the fan assembly 1302 and/or the solar panel.

The installation of the base 1304 can include various activities. For instance, a user can enter the crawl way 105 (or other space opposite the intended location of the fan system) and mark an appropriate location for the center of the fan system. Often, the user will identify a location between two rafters 324 and mark that location with any convenient writing, marking, etc. tool. The user can then drill a hole through the roof 104 so that the desired location of the fan system becomes apparent from the other side of the roof. The user, moreover, can then access the other side of the roof and use a compass or other tool to mark the outline of the duct-space defined by the base 1304. Using that marking as a guide, the user can then cut through the roof to define the penetration 322 through which air will flow as induced by the fan system. Thus, the user can locate the position of the to-be-installed fan system as indicated at reference 2108.

Further still, the user can lift the roofing material 328 of the roof 102 adjacent to the penetration 322 in preparation for installing the base 1302 and, if desired, apply caulking (or some other sealant) to the roof deck 326 in preparation for sealing the base 1304 to the roof. The user can then, if desired, slide one side of the flashing 1310 under an appropriate portion of the roofing material 328 and then maneuver the base 1302 alone (sans the fan assembly 1302, riser 1303, etc.) into its final place on the roof 104 and/or over the penetration 322. Thus, much of the inconvenience, difficulty, awkwardness, etc. of working with these bulky, heretofore available fan systems can be eliminated. This condition can facilitate the work, reduce associated expenses, and/or reduce the likelihood/severity of mistakes, oversights, etc. Furthermore, the user can use fasteners to fasten the base 1304 to the roof deck 326. See reference 2110.

FIG. 21 also illustrates (at reference 2116) the method of coupling a riser, such as riser 1303 of FIG. 13 to a base, such as the base 1304 of FIG. 13. More particularly, in accordance with embodiments, the user can maneuver the riser 1303 to the vicinity of the base 1304 (after it is installed if desired) and roughly align coupling halves, such as coupling halves 1312 and 1310/1314 of FIG. 13 or coupling halves 1802 and 1804 of FIG. 18, with one another. Once the halves 1802 and 1804 are roughly aligned, the user can engage the male half 1802 and the female half 1804 and then (by maneuvering/twisting the riser 1303) translate one relative to the other thereby causing a latch, such as latch 1820 of FIG. 18, to latch/lock the halves together. Thus, the user can mount the riser 1303 to the base 1304 and do so without tools. Note that at this point that much of the overall two-piece fan system (in terms of physical envelope size) is installed.

In many situations, the fan assembly 1302 (including the fan motor) might be the heavier of the two (or three or more) pieces of the fan system. Thus, at reference 2118, the method shows the user installing a fan assembly, such as fan assembly 1302 of FIG. 13, as a separate piece on the base 1304 and/or riser 1303. Since the user is doing so with only the fan assembly 1302 (and not the base 1304 or riser 1303) in their hands, such activities might be easier, more convenient, less awkward, etc. than would otherwise be the case. Thus, the user can maneuver the fan assembly 1302 into the proximity of the base/riser 130411303 and roughly align corresponding coupling halves, such as coupling halves 1312 and 1310/1314 of FIG. 13 or coupling halves 1802 and 1804. Moreover, the user can then latch the coupling in place with a twist. In the alternative, or in addition, types of couplings other than twist-on/off couplings can be used to couple the various assemblies together. For instance, bayonet fittings could be used. Of course, the user could install the fan assembly 1302 with a riser 1303 attached thereto if desired.

In some embodiments, the user can attend to certain electrical portions of the installation. For instance, the user can place the thermostat 2012 at a location where it can sense temperatures in (or associated with) the crawl way 105. See reference 2120. If the thermostat is a component of the fan assembly 1302, the user might not need to do so though since it could be pre-located in the fan assembly 1302 (or attached thereto) during manufacture. In accordance with embodiments though, the user can connect the connectors 2020 to line power if desired. See reference 2121.

Method 2100 also shows that the user can mount a solar panel to the fan assembly as at reference 2122. If the solar panel 1306 is a separate component of the fan assembly 1302, the user can also connect the connections 2022 (FIG. 13). Additionally, in accordance with embodiments, the user can point the solar panel 1306 toward the sun by adjusting the adjustable brackets 1308 and, perhaps, locking them it in a selected position. Note also that with angled risers, the installation of the angled riser (disclosed elsewhere herein) can include adjusting the orientation of that angled riser to be compatible with obtaining a satisfactory “sun angle” for the solar panel 1306. See reference 2124. FIG. 21 also shows that the user can turn the fan system on as indicated at reference 2128 and/or verify its operation.

At some point, though, it might become desirable to change the fan system. For instance, use of the building, occupancy of the building, heat loads, etc. could change or the user might desire a different fan specifications. See reference 2130. Thus, the user could select another fan assembly 1302 and/or riser(s) 1303. Since the base 1304 is already installed, the user need not select another base 1304 although they could. See reference 2132. Such features allow suppliers of these fan systems to reduce their stocks of fan system parts since they can mix and match fan assemblies, risers, bases, etc. as desired by end users. Moreover, here, the user could then repeat all or portions of method 2100 as indicated at reference 2134. Note that if the inter-change of a fan assembly is interrupted for some time, covering the aperture of the riser is generally casier, more convenient than trying to cover a raw penetration through the roof. For instance, a plastic bag can be stretched over the riser to close the aperture as opposed to having to place a tarp over a penetration and some how securing the tarp and excluding runoff from entering the penetration anyway. Of course, if the user is satisfied with the fan system as installed or for other reasons, method 2100 can end.

FIG. 22 illustrates a quick attachment coupling for multi-piece fan systems. The multi-piece fan system 200 of the current embodiment comprises two assemblies 2202 and 2204 which can be bases, risers, fan assemblies etc. As FIG. 22 illustrates the multi-piece fan system 2200 includes a quick attachment coupling 2240. In the current embodiment, the quick attachment coupling 2240 includes a flexible detent 2250, catch, dog, pawl, ratchet, etc. and a post 2204 or other protrusion which the flexible detent 2250 can engage. When the two assemblies 2202 and 2204 are mated, the post 2254 (on one assembly 2204) extends through an aperture 2252 defined by the other assembly 2202. The flexible detent 2250 operationally couples with the assembly 2202 which defines the aperture 2252 in the current embodiment. The flexible detent 2250 can be made of metal, plastic, etc.

Moreover, the flexible detent 2250 is positioned relative to the aperture 2252 (and/or the post 2254) such that when the assemblies rotate and/or twist relative to one another, the flexible detent 2250 engages the post and flexes allowing the post 2250 to pass relative to itself. A hook 2260 defined by the flexible detent 2250 can then catch on the post 2254 thereby securing the assemblies 2202 and 2204 to each other. Note that the flexibility of the flexible detent 2250 (and/or shape of the hook 2260) can be selected so that some select amount of torque must be applied (in the opposite direction of rotation) to overcome the detent and free the flexible detent 2250 from the post 2254. In the alternative, or in addition, the quick attachment coupling 2240 can be disengaged, manually, with a tool, etc. by pressing on, pulling, etc. the flexible detent 2250 and/or post 2254.

While certain terms have been used herein which might imply certain directions or orientations, these terms are used merely for the sake of convenience and are non-limiting. For instance, the term “height” is a dimensional term as used herein but does not imply that that dimension necessarily lies along a vertical or even approximately vertical direction. Thus, fans, fan assemblies, risers, bases, etc. of embodiments disclosed herein are not limited to any particular orientation.

Embodiments provide two-piece fan systems with highly efficient solar panels. These solar panels can be monocrystalline and can produce 22 watts at 17.6 VDC/1.22 amps. Fan motors of embodiments can be brushless, high reliability, high efficiency motors capable of operating at 6-100 VDC and in some embodiments (more specifically 12-36 VDC). Moreover, fans of embodiments can include sets of five nylon/polymeric blades. Fans comprising such motors and blades can ventilate areas of 1800 square feet and can induce 1300 CFM (cubic feet per minute) and/or more or less airflow. In some embodiments, the fan assemblies include one AC motor wired to interconnects at which it can receive AC power (for instance 120 VAC) from the building power system and one DC motor wired to interconnects at which it can receive DC power from a solar panel and/or other source.

Housings of embodiments can be made from aluminum, galvanized steel, various plastics such as automotive grade ABS, high-impact resistant plastic, etc. Housings of the current embodiment can also be UV (ultraviolet) stabilized and can include embedded fire retardant resin(s). These housings can also be configured to double lock with their respective (and separate) bases. In embodiments, the double locking can be via keyhole standoffs which guide the two connecting pieces together. A flexible metal pin on one or the other of the mating pieces/assemblies can be configured to snap in place to secure the assemblies together. Because the bases and housings/fan assemblies of embodiments are separate components, installation, support, maintenance, etc. can be easier than with heretofore-available fan systems. In some embodiments, fan assemblies can be about 24″ by about 24″ by about 7″ in size and can weigh about 26 pounds. Bases of the current embodiment can be about 28″ by about 28″ by about 11.” Furthermore, fan systems of embodiments comprise thermal switches and thermoballs (and/or other devices capable of measuring temperature which can regulate the various fan systems disclosed hercon (for instance) 36″ cables. Two-piece fan systems of embodiments convert passive ventilation to active ventilation and can extend the life of roofs, AC units, stored valuables, etc. and can reduce moisture and mildew. Two-piece fan systems of embodiments are resistant to even extreme weather and windstorm rated and certified. Such fans reduce HVAC costs and cooling cycles. They also increase air exchanges so that even if solar heat causes temperatures to soar in attics, crawl spaces, and the like, properly balanced fans of embodiments increase air exchanges to as many as ten times per hour. The increased air exchange in accordance with embodiments keeps living spaces cooler and saves building owners money.

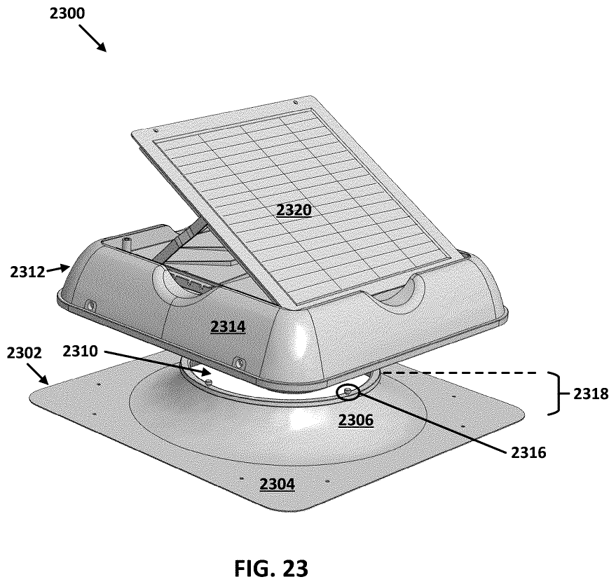

FIGS. 23-28 illustrate various views of an exemplary ventilation system 2300 according to embodiments of the present invention. The exemplary ventilation system 2300 of FIGS. 23-28 is similar in structure to the two-piece fan systems described with reference to FIGS. 5-20 and FIG. 22. FIG. 23 illustrates a perspective view of an exemplary ventilation system 2300 according to embodiments of the present invention. The exemplary ventilation system 2300 of FIG. 23 includes a base unit 2302 and a fan unit 2312.

The base unit 2302 of FIG. 23 has a mounting platform 2304 for connecting the base unit 2302 to a surface having a surface opening. The surface to which the mounting platform 2304 of FIG. 23 is connected may, for example, be the roof deck 326 of FIG. 3 having a penetration 322. Of course, this is for example only and not for limitation. The exterior surface of any enclosed space may be useful for connecting a mounting platform of a ventilation system according to embodiment of the present invention. For example, the ventilation system 2300 of FIG. 23 may be mounted vertically, for example, to a wall having a hole through which ventilation is desired or mounted to a vertical wall in a horizontal configuration using an ‘L’ shaped riser adapter.

Even though the mounting platform 2304 of FIG. 23 is depicted as flat in shape, the mounting platform for connecting a base unit according to embodiments of the present invention might vary in shape from one particular surface to another. For example, exemplary mounting platforms useful in embodiments of the present invention may have features or configurations that correspond to various roof features or configurations, thereby permitting such exemplary mounting platforms to mate and/or connect with such roofs. See, for example, the two bases 1706 and 1708 of FIG. 17, which respectively define flashings with corresponding corrugated trapezoidal and sinusoidal cross-sections, and the base 1904 of FIGS. 19 and 19A that define an adaptor 1910 shaped and dimensioned to mate with the roof curb 1906 and to seal thereto.

The base unit 2302 of FIG. 23 also includes a base collar 2306. The base collar 2306 of FIG. 23 extends away from the mounting platform 2304 (and the surface to which the mounting platform 2304 connects) toward the location where the fan unit 2312 connects to the base unit 2302. Because the base collar 2306 of FIG. 23 rises above the plane established by the mounting platform 2304, the base collar 2306 provides a gap region 2318 between the mounting platform 2304 and the fan unit 2312. The gap region 2318 of FIG. 23 keeps the fan unit 2312 above any water runoff from the surface on which the mounting platform 2304 is connected and provides a space into which the fan unit can expel air being ventilated by the exemplary ventilation system 2300. Such a configuration allows for the air outlets of the exemplary fan unit 2312 to be configured on the underside of the fan unit 2312 which helps prevent precipitation such as rain or snow from entering the air outlets.

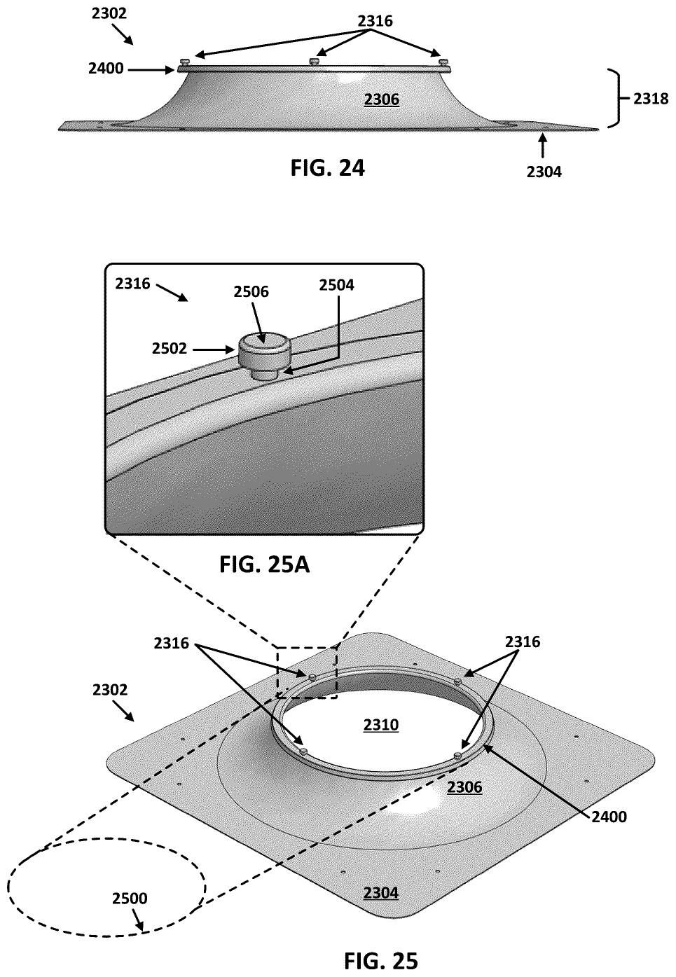

For further description of the base collar 2306 and the gap region 2318, FIG. 24 illustrates a left view of the exemplary base unit 2302 useful in ventilation systems according to embodiments of the present invention, and FIG. 25 illustrates a perspective view of the exemplary base unit 2302 useful in ventilation systems according to embodiments of the present invention.

The base collar 2306 of FIGS. 23, 24, 25, and 25A serves to form a perimeter 2500 (shown on FIG. 25) of a base opening 2310 through the base unit 2302 that corresponds to the surface opening through the surface to which the mounting platform 2304 is connected. The base opening 2310 formed by the base collar 2306 of FIG. 23 need not precisely match the size and shape of the opening in the surface to which the exemplary ventilation system 2300 is mounted. The base opening 2310 of FIG. 23 may be smaller or larger than such an opening the surface (e.g., roof).

As shown in FIG. 24, the base collar 2306 includes a flange 2400 around the base collar 2306 at an opposite end of the base collar from the mounting platform 2304. The flange 2400 of FIG. 24 is structured as a flat ring at the top of the base collar 2306. This flange 2400 provides additional structural integrity for the base collar 2306 and provides a platform for connecting to a fan unit such as the fan unit 2312 shown in FIG. 23. As depicted, the space between the flange 2400 and the mounting platform 2304 of FIG. 24 form the gap region 2318.

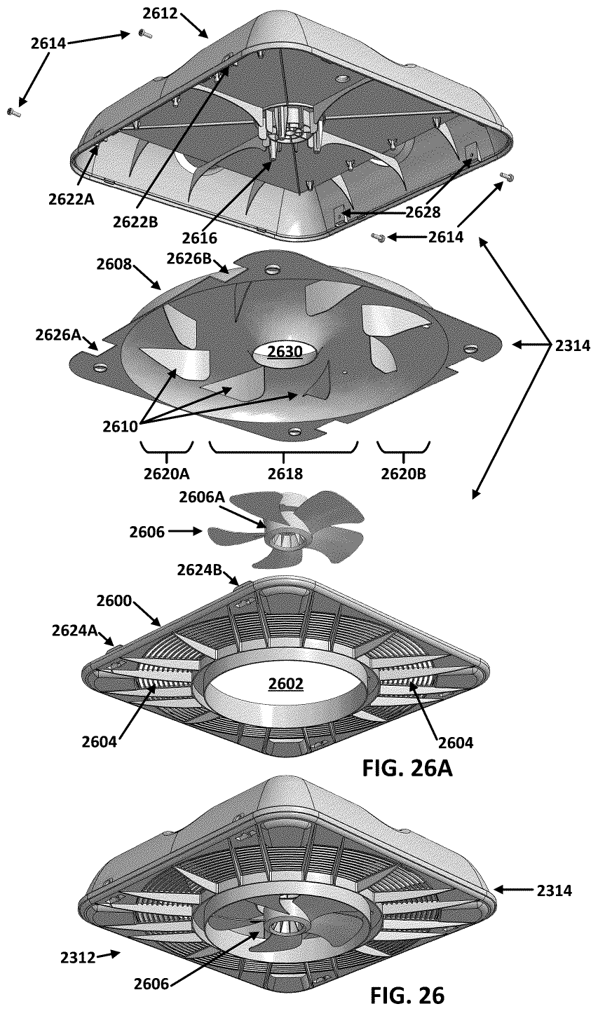

As mentioned, the exemplary ventilation system 2300 of FIGS. 23-28 also includes a fan unit 2312. The exemplary fan unit 2312 is described with reference to FIGS. 23, 26 and 26A. FIG. 26 illustrates a perspective view of the exemplary fan unit 2312 useful in ventilation systems according to embodiments of the present invention. FIG. 26A illustrates an exploded view of the exemplary fan unit 2312 useful in ventilation systems according to embodiments of the present invention.

The exemplary fan unit 2312 of FIG. 23 includes a fan housing 2314 and a fan (2606 in FIGS. 26 and 26A). The fan housing 2314 of FIG. 23 is configured to receive air through an inlet (2602 in FIG. 26A) and expel the air through an outlet (2604 in FIG. 26A). The inlet of the fan housing 2314 in the example of FIG. 23 is configured to correspond to the base opening 2310 so that air passing through the base opening 2310 enters the fan housing 2314 through the air inlet (2602 in FIG. 26A), which in this example is circular in shape as shown in FIGS. 26 and 26A. The outlet of the fan housing 2314 of FIG. 23 is configured as a ring around the inlet 2602 (shown in FIG. 26A). The outlet 2604 discharges the air into the gap region 2318 of FIG. 23 for further dissipation into the surrounding environment.

The exemplary fan housing 2314 of FIGS. 23, 26, and 26A includes a fan housing base 2600, an airflow diverter 2608, and a fan housing cover 2612, all shown in FIG. 26A. In the exemplary embodiment illustrated, the fan housing base 2600, the airflow diverter 2608, and the fan housing cover 2612 are held together with screws 2614. Such attachment is for example only and not for limitation. These components 2600, 2608, and 2612 may be held together via snap attachments, quick-release attachments, or may even be molded together. The fan housing cover 2612 of FIG. 26A provides the structure for connecting other components and protecting the inner components from the weather outside of the fan unit 2312. For example, the fan housing cover 2612 of FIG. 26A includes slots 2622A, 2622B for receiving the connection tabs 2624A, 2624B (also shown on FIG. 28) on the fan housing base 2600 after passing through tab openings 2626A, 2626B of the airflow diverter 2608-effectively sandwiching the airflow diverter 2608 between the fan housing base 2600 and fan housing cover 2612. The same structure exists on the other side of the fan housing cover 2612 where slots 2628 are configured. The fan housing base 2600, the airflow diverter 2608, and the fan housing cover 2612 are held together with screws 2614 that pass through holes in the slots 2622A, 2622B and connection tabs 2624A, 2624B. In addition, the fan housing cover 2600 includes screw receptacles or housings that enable the fan 2606 to be held in place via screws (not shown) that pass through an opening 2630 in the air flow diverter 2608.

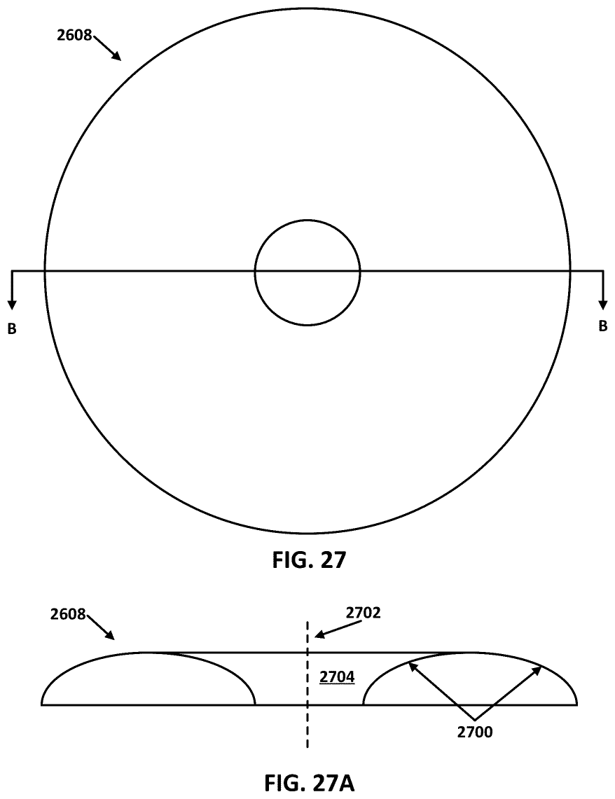

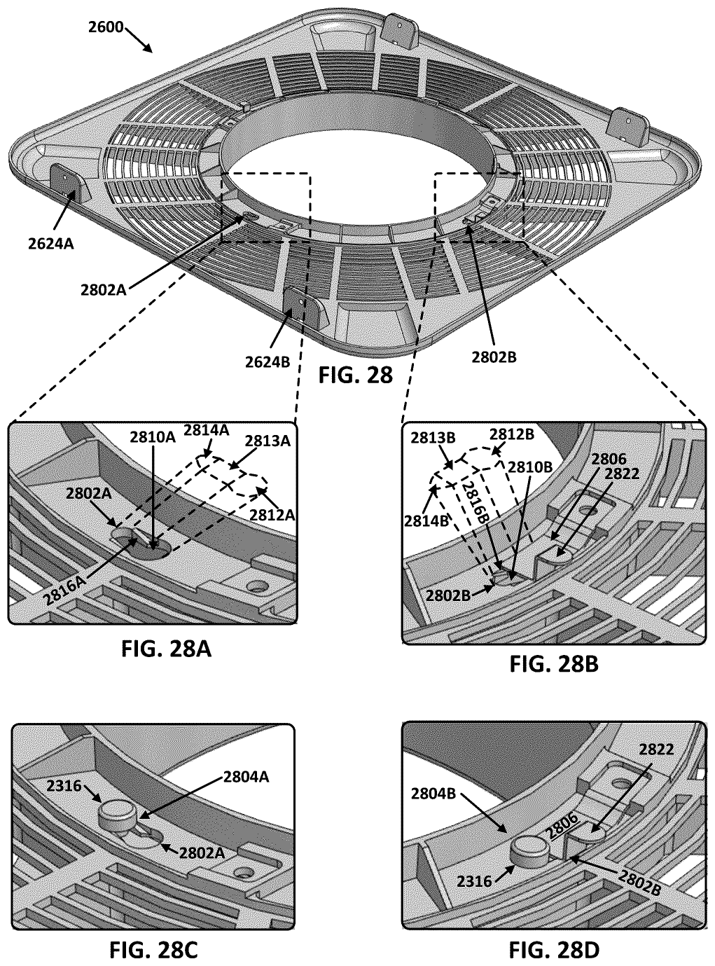

The air flow diverter 2608 of FIG. 26A is formed to guide the air from the inlet 2602 to the outlet 2604. In the exemplary fan unit 2312, the airflow diverter 2608 of FIG. 26A is configured to be ovoidal in shape. The ovoidal shape of the airflow diverter 2608 of FIG. 26A refers to the shape being similar to the 3-dimensional surface generated by rotating an oval curve around an axis. For further explanation, FIG. 27 illustrates a top view of the airflow diverter 2608 of FIG. 26A. FIG. 27A illustrates a cross-sectional view of the airflow diverter 2608 of FIG. 27 along line B-B. In FIG. 27A, an oval curve 2700 is rotated about a vertical axis 2702 to form 3-dimensional surface 2704.

Turning back to FIG. 26A, the airflow diverter 2608 has an inner region 2618 and an outer region 2620A, 2620B. The inner region 2618 of the airflow diverter 2608 is configured adjacent to the inlet 2602 to allow air to flow through the air inlet 2602 into the inner region of the 2618 of the airflow diverter 2608. The inner region 2618 of FIG. 26A is a circular space configured nearest to the center of the airflow diverter 2608. The outer region 2620A, 2620B of FIG. 26A is a ring configured around the inner region 2618 of the airflow diverter 2608. The demarcation between the inner region 2618 and the outer region 2620A, 2620B of FIG. 26A corresponding to the configuration of the inlet 2602 and outlet 2604 formed in the fan housing base 2600.

Air flows into the inner region 2618 as the fan 2606 rotates the fan blades and draws air from outside the fan unit 2312 up through the base opening (2310 on FIG. 23) and further through the inlet 2602 of FIG. 26A. Air moves along the airflow diverter 2608 from the inner region 2618 to the outer region 2620A, 2620B in FIG. 26A as the fan 2606 continues to draw air into the inner region 2618, thereby displacing the air already in the inner region 2618 and forcing the air to move to the outer region 2620A, 2620B of the airflow diverter 2608. The outer region 2620A, 2620B is configured adjacent to the outlet 2604. As air continues to be moved from the inner region 2618 to the outer region 2620A, 2620B, the air that is already present in the outer region 2620A, 2620B is displaced and expelled through the air outlet 2604 into the gap region 2318 (shown on FIG. 23) for dissipation into the surrounding environment.

In the example of FIG. 26A, the airflow diverter 2608 includes various vanes 2610 for directing the air from the inlet 2602 to the outlet 2604. This prevents air from just circulating around and around the outer region 2620A, 2620B of the airflow diverter 2608 and forces air through the outlet 2604. The vanes 2610 of FIG. 26A increase the overall efficiency of the fan 2606 moving air through the inlet 2602 and subsequently expelling that air through the outlet 2604, which has the advantage of saving power in the exemplary system.

One of skill in the art will recognize that other configurations of an airflow diverter and placement of the inlet and outlet may be useful in embodiments of the present invention. Factors that may effect the configurations of an airflow diverter and placement of an inlet and outlet in such other embodiments may include the overall orientation of the ventilation system so as to avoid precipitation entering the system, the shape of the fan housing cover or overall shape of the ventilation system for a particular application, the size of the fan required to ventilate a particular area, and other such factors as will occur to those of skill in the art.

The fan housing 2314 as shown in FIGS. 26 and 26A provides the structure for configuring the fan (2606 of FIGS. 26 and 26A) inside the fan unit 2312. The fan blades of the exemplary fan (2606 in FIGS. 26 and 26A) inside the fan housing 2314 are configured to fit inside and operate within the air inlet 2602. For optimal efficiency at moving air, the fan blades are sized to cover the entire area of the air inlet 2602 without touch the sides of the inlet 2602. The motor of the fan (2606 in FIGS. 26 and 26A) and the opening 2630 in the air flow diverter 2608 are configured to be similar in size such that the fan motor fits inside the opening 2630 of the air flow diverter 2608. Such a configuration increases the efficiency of the airflow diverter 2608 and fan 2606 at moving the air from the inlet 2602 to the outlet 2604 because less air gets trapped in the region between the fan motor and the opening 2630 of the air flow diverter 2608 if the fan motor and the opening 2630 are similar in size. In the example of FIGS. 26 and 26A, allowing the fan motor to be tucked inside the opening 2630 allows the overall height of the fan unit to be less, thereby promoting a lower profile ventilation system that is subject to less wind shear forces than a fan unit with a larger height.

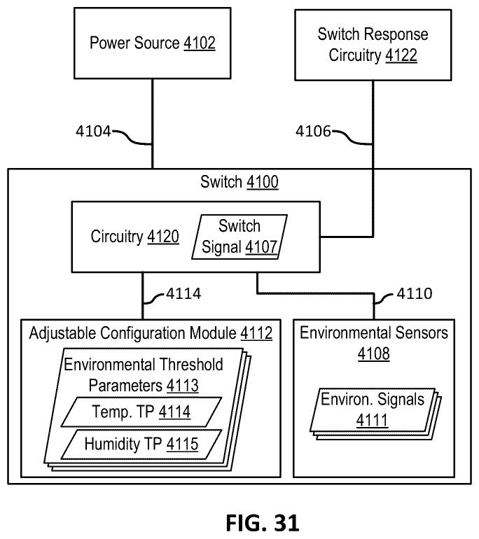

The fan (2606 in FIGS. 26 and 26A) inside the fan housing 2314 of FIG. 23 is capable of connecting to a power source that enables the fan to move the air from the inlet to the outlet. In the example of FIG. 23, the power source is solar power provided by solar cells of solar panels 2320 mounted to the top of the fan housing 2314. The solar panels 2320 of FIG. 23 are electrically connected to the fan (2606 in FIGS. 26 and 26A) using various electrical conductors. An ultra-low power adjustable temperature-humidity sensor switch (4100 of FIGS. 31, 38, and 39) described with reference to FIGS. 31-39 may also be connected to the solar power source, which includes the solar panels 2320 of FIG. 23. The ultra-low power adjustable temperature-humidity sensor switch (4100 of FIGS. 31, 38, and 39) described with reference to FIGS. 31-39 is connected to the motor (2606A in FIG. 26A) of the fan (2606 in FIGS. 26 and 26A) and controls when the fan (2606 in FIGS. 26 and 26A) is activated and/or deactivated by turning on and/or turning off power to the exemplary fan based on a switch signal received from the switch (4100 of FIGS. 31, 38, and 39). The switch (4100 of FIGS. 31, 38, and 39) provides a switch signal on its output conductor to activate the motor (2606A in FIG. 26A) based on comparing measured temperature and humidity signals to user-specified threshold parameters. In this way, the switch (4100 of FIGS. 31, 38, and 39) can trigger the exemplary ventilation system (2300 of FIG. 23) to remove excess heat and moisture from an attic. When the temperature or humidity exceeds a specified level, the switch can activate a motor to start fans or open vents to promote air circulation and prevent mold or condensation issues. The ability to use the ultra-low power switch to automatically activate a vent when temperature and/or humidity exceeds user-defined thresholds provides an energy efficient way to control attic ventilation to reduce moisture issues.

While in the example of FIG. 23, the power source is solar power, other types of power sources may also be utilized in ventilation systems according to embodiments of the present invention such as, for example, A/C power sources, D/C power sources (e.g., battery power sources), mechanical power sources (e.g., wind turbine).

The exemplary ventilation system 2300 of FIGS. 23-28 also includes quick connect interfaces (2804A, 2804B in FIGS. 28C and 28D). Each quick connect interface 2804A, 2804B of FIGS. 28C and 28D consists of a pair of interlocking parts can be coupled and decoupled by moving the interlocking parts relative to one another. The term ‘quick connect’ describes the joinder or dis-joinder of at least two components by hand without the aid of additional tools. In the example of FIGS. 28C and 28D, each of the exemplary quick connect interfaces 2804A, 2804B consist of a base feature 2316 integrated into the base unit 2302 and a fan housing feature (2802A, 2802B shown in FIGS. 28 and 28A-D) that is integrated into the fan unit 2302. The base feature 2316 and the fan housing feature 2802A, 2802B are capable of detachably connecting together to secure the fan unit 2312 to the base unit 2302.

FIG. 25A is a magnified view of an exemplary base feature 2316 shown in FIG. 25. The exemplary base features 2316 shown in FIGS. 23-25, 28C, and 28D are mounted to the base collar 2306. More specifically, the base features 2316 are mounted to the flange (2400 on FIG. 24) of the base collar 2306. Each base feature 2316 of FIGS. 23-25, 28C, and 28D is implemented as a detent 2506 that extends out from the base collar 2306 away from the mounting platform 2304. The detent 2506 of FIG. 25A serves as a catch that prevents motion until released in the exemplary quick connect interfaces illustrated with reference to the Figures. In the example of FIG. 25A, the detent 2506 includes a detent head 2502 and a detent body 2504. The detent head 2502 of FIG. 25A is larger than the detent body 2504. This size differential operates to allow the base feature 2316 to lock into place with the corresponding feature of the quick connect interface on the fan unit 2312.

The corresponding features to the base features 2316 on the exemplary fan unit 2312 of the quick connect interfaces 2804A, 2804B (shown on FIGS. 28C and 28D are the fan housing features 2802A, 2802B (shown on FIGS. 28 and 28A-D). The fan housing features 2802A, 2802B of the quick connect interfaces 2804A, 2804B are integrated into the fan housing base 2600. Each fan housing feature 2802A, 2802B consists of a receptacle 2810A, 2810B capable of receiving a corresponding base feature 2316 of the quick connect interface 2804A, 2804B. FIGS. 28A-B depict the receptacles 2810A, 2810B ready to receive the base features 2316. FIGS. 28C-D depict the base features 2316 engaged and locked into place in the receptacles 2810A, 2810B. The receptacles 2810A, 2810B form holes through the fan housing base 2600. The configuration of the holes formed by the receptacles 2810A, 2810B and the configuration of the base features 2316 prescribed how the two component interact to couple and decouple the base unit 2302 and the fan unit 2312.

Each receptacle 2810A, 2810B of FIGS. 28A-B defines an entry region 2812A, 2812B, a transition region 2813A, 2813B, and a locking region 2814A, 2814B. These regions are shown on FIGS. 28A-B using dotted lines for clarity and to avoid cluttering. Each entry region 2812A, 2812B is capable of receiving the base feature 2316. As such, each entry region 2812A, 2812B must be at least as large as the detent head of the base feature 2316. Each locking region 2814A, 2814B is capable of securing the base feature 2316 in the receptacle 2810A, 2810B. As such, each locking region 2814A, 2814B of FIGS. 28A-B should be configured smaller than the detent head of the base feature 2316 but larger than the detent body of the base feature 2316. As shown in FIGS. 28C-D, the detent heads of the base features 2316 being larger than the locking regions 2814A, 2814B prevents the base features 2316 from being pulled back through the receptacles 2810A, 2810B without rotating the base features 2316 out of the locking regions 2814A, 2814B. As one of skill in the art can appreciate, the thickness of the receptacles 2810A, 2810B affect the minimum length of the detent body of the base features 2316. The thicker the fan housing base 2600 forming the receptacles 2810A, 2810B, the longer the detent bodies of the base features 2316 need to be.

Each transition region 2813A, 2813B is capable of guiding the base feature 2316 from entry region 2812A, 2812B to the locking region 2814A, 2814B. To assist with guiding the base feature 2316 from entry regions 2812A, 2812B to the locking regions 2814A, 2814B, each transition region 2813A, 2813B provides an incline 2816A, 2816B that guides the base feature 2316 into the locking region 2814A, 2814B. Each incline 2816A, 2816B of FIGS. 28A-B is oriented to pull the base unit 2302 and the fan unit 2312 together as the base feature 2316 moves into the locking region 2814A, 2814B.

In the example of FIGS. 28B, 28D, the fan housing feature 2802B includes a catch 2806 that is implemented as a flat spring with finger tab 2822. The catch 2806 of FIGS. 28B, 28D is configured to prevent the base feature 2316 from backing out of the locking region 2814A, 2814B after passing a predetermined position. The predetermined position is set by the size of the detent head and the length of the catch 2806. As the detent head is received into the entry region 2812B, the catch 2806 is forced upward to make room for the detent head to protrude through the receptacle 2810B. The detent head of the base feature 2316 slides upward along the incline 2816B into the locking region 2814B as the fan unit 2312 and the base unit 2302 are rotate relative to one another. Upon entering the locking region 2814B, the detent head of the base feature 2316 clears the end of the catch 2806. The spring loaded catch 2806, having been under tension from the detent head of the base feature 2316 forcing the catch 2806 upward, then snaps down and holds the base feature 2316 in place in the locking region 2814B as shown in FIG. 28D. When an operator is ready to decouple the base unit 2302 from the fan unit 2312, the operator merely lift up on the finger tab 2822 so that the catch 2806 is raised above the detent head of the base feature 2316 and then rotates the fan unit 2312 and the base unit 2302 relative to one another in the direction opposite from when the fan unit 2312 and the base unit 2302 were coupled.

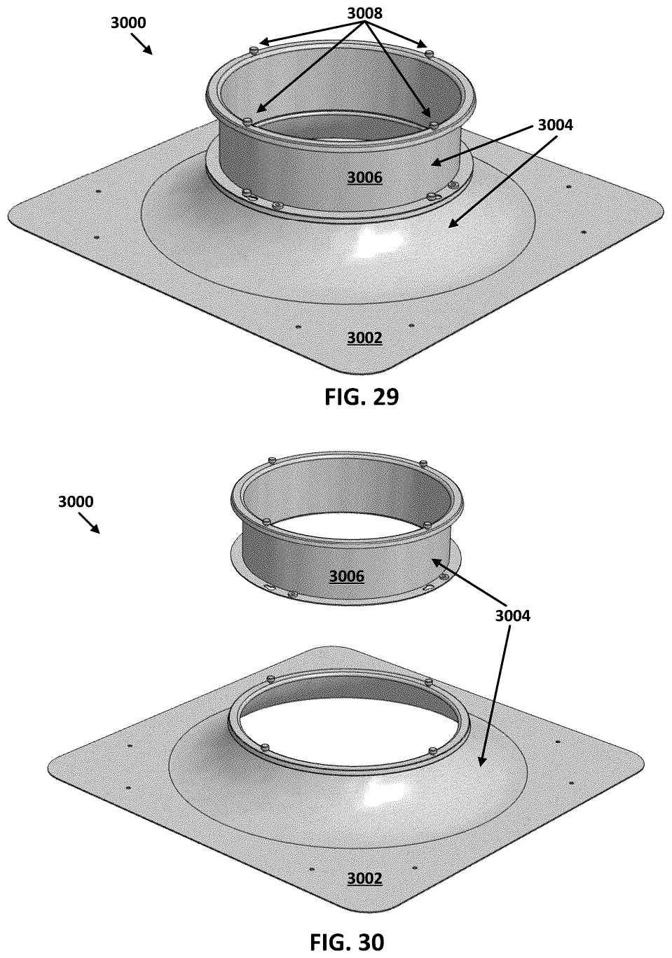

As mentioned above, in some applications, raising a fan unit higher might provide advantages. Accordingly, some base units useful in ventilation systems according to embodiments of the present invention, may include a riser. FIG. 29 sets forth a perspective view of a base unit 3000 useful in ventilation systems according to embodiments of the present invention. FIG. 30 sets forth an exploded view of a base unit 3000 depicted in FIG. 29. The base unit 3000 of FIGS. 29 and 30 includes a mounting platform 3002 and a base collar 3004, all structured similar to the base unit 2302 described with reference FIGS. 23-25. The base collar 3004 of FIGS. 29 and 30, however, also includes a detachable riser 3006. The riser 3006 connects to the rest of the base collar 3004 in FIGS. 29 and 30 using quick connect couplings similar to the manner in which the fan unit 3212 of FIG. 23 connects to the base collar 2306 and described with reference to FIGS. 28 and 28A-D. In turn, an exemplary fan unit may attach to the riser 3006 in the same manner as the fan unit 3212 of FIG. 23 connects to the base collar 2306. This is accomplished because the base features 3008 of FIG. 29 are mounted to the detachable riser 3006 in the same manner that that the base features 2316 are mounted to the base collar 2306 in FIGS. 23-25. That is, the base features 3008 are detents having a detent body and detent head that protrude from the riser 3006 away from the mounting platform 3002.

### Exemplary Batteryless Ultra-Low-Power Adjustable Temperature-Humidity Sensor Switches

The present invention relates to temperature and humidity sensing devices, specifically to batteryless ultra-low-power adjustable direct current (DC) temperature humidity sensor switches. Such devices may be widely used in various applications that require accurate monitoring and control of environmental conditions. Embodiments of the present invention combine advanced sensor technology with energy-efficient design principles to enable accurate and reliable temperature and humidity monitoring while minimizing power consumption.

The ultra-low-power design of the sensor switch allows for extended battery life, making it ideal for applications where power availability is limited or where long-term operation is required. By reducing energy consumption, the device enhances sustainability and lowers the overall cost of ownership.

Moreover, the adjustable nature of the sensor switch may be implemented in a variety of ways-some ways that simplify its operation and installation and other ways that provide flexibility to address complex factors that affect adjustability. For example, the device may be pre-calibrated with standardized temperature and humidity thresholds, ensuring consistent and reliable measurements across different installations while providing adjustability. This simplicity enables easy integration into various systems and eliminates the need for complex configuration processes. By combining low power consumption with pre-calibrated thresholds, this invention offers an efficient and user-friendly solution for temperature and humidity monitoring in a wide range of applications.

In other examples of the present invention, the device's adjustable feature is achieved through intuitive control interfaces or software programming, enabling easy configuration and adaptation to changing conditions. This capability enhances the versatility and effectiveness of the sensor switch, making it suitable for a wide range of applications where precise and customizable temperature and humidity monitoring are essential.

The adjustable nature of the sensor switch in a low power consumption environment is a key advantage. Users can customize the temperature and humidity thresholds according to their specific application requirements. This flexibility allows for tailored monitoring and control, ensuring that the sensor switch can adapt to various environmental conditions and trigger appropriate actions or alerts based on user-defined parameters. In summary, the ultra-low-power adjustable DC temperature humidity sensor switch according to embodiments of the present invention provides a significant advancement over existing sensing devices.

Exemplary ultra-low power adjustable temperature-humidity sensor switches according to embodiments of the present invention are described with reference to the accompanying drawings, beginning with FIG. 31. FIG. 31 sets forth a block diagram illustrating an exemplary ultra-low power adjustable temperature-humidity sensor switch (4100) according to embodiments of the present invention.

The ultra-low power adjustable temperature-humidity sensor switch (4100) of FIG. 31 includes a power conductor (4104) configured to receive power from a power source (4102). The power source (4102) of FIG. 31 is implemented as an ultra-low power direct current (DC) power supply. Ultra-low power direct current (DC) power supplies play a crucial role in various electronic devices and systems that require efficient and reliable power management. These power supplies are designed to provide a stable and regulated DC voltage while consuming minimal energy. Such power supplies are particularly essential in battery-powered devices, wearable electronics, Internet of Things (IoT) devices, and other energy-constrained applications where power efficiency is paramount.

One of the key features of ultra-low power DC power supplies is their ability to operate in a wide input voltage range, accommodating different power sources such as batteries, solar panels, or energy harvesting modules. They are designed with high-efficiency voltage regulators, such as low-dropout regulators (LDOs) or switch-mode power supplies (SMPS), which minimize power losses and maximize energy utilization. These power supplies also employ advanced power management techniques, such as sleep modes, power gating, and dynamic voltage scaling, to further optimize power consumption based on the device's operational requirements.

Moreover, ultra-low power DC power supplies incorporate various energy-saving mechanisms to minimize standby power consumption. These include intelligent power management algorithms that monitor the device's activity level and adjust power delivery accordingly. Additionally, some power supplies employ power conversion techniques, such as energy harvesting or power scavenging from ambient sources, to supplement or recharge the primary power source, thus extending the device's overall battery life.

Overall, ultra-low power DC power supplies enable energy-efficient operation and prolonged battery life in a wide range of electronic devices. With advancements in power management technologies and the increasing demand for portable and battery-powered applications, these power supplies continue to evolve, offering enhanced efficiency, smaller form factors, and increased integration to meet the growing needs of the energy-constrained world.

In the field of power generation and distribution, there is a growing need for sustainable, efficient, and reliable energy sources that can operate independently of traditional battery systems. Batteryless ultra-low power direct current (DC) power sources offer a promising solution to this challenge by harnessing energy from various ambient sources, such as solar, thermal, or mechanical energy, and converting it directly into usable DC power. These innovative power sources eliminate the need for bulky, expensive, and potentially hazardous batteries, thereby reducing maintenance costs, environmental impact, and operational complexity. Moreover, the ultra-low power consumption of these devices enables them to function efficiently in remote, inaccessible, or size-constrained applications, such as wireless sensor networks, wearable electronics, and implantable medical devices. By providing a continuous, self-sustaining power supply without the limitations and drawbacks associated with traditional batteries, batteryless ultra-low power DC power sources represent a significant advancement in the field of energy harvesting and have the potential to revolutionize the way we power our electronic devices in the future.

Solar panels are an excellent source of batteryless ultra-low power DC power, especially in applications where energy efficiency and sustainability are crucial. Solar panels harness the energy from sunlight and convert it into usable electrical power. They are designed to provide a consistent and reliable DC voltage, making them ideal for powering low-power electronic devices, sensors, and other energy-constrained systems.

One of the primary advantages of solar panels is their ability to generate electricity without relying on fossil fuels or external power sources. They operate by utilizing photovoltaic cells that absorb sunlight and generate a DC current. These panels can be deployed in various environments, ranging from residential rooftops to remote outdoor locations, enabling energy harvesting in both urban and off-grid settings.

Ultra-low power solar panels are specifically engineered to maximize energy conversion efficiency and minimize power losses. They incorporate advanced solar cell technologies, such as monocrystalline or polycrystalline silicon cells, which have high conversion efficiency and excellent performance in low-light conditions. Additionally, these panels often feature bypass diodes that optimize power output by minimizing the impact of shading or partial obstruction on the overall solar array.

To regulate the DC power output from solar panels, charge controllers or maximum power point tracking (MPPT) systems are commonly employed. These devices ensure that the solar panel operates at its maximum power point, maximizing the energy harvested from the sunlight. They also provide voltage regulation and protection against overcharging or excessive power fluctuations, safeguarding the connected devices or battery systems.

In summary, solar panels are a reliable and environmentally friendly source of ultra-low power DC power. They offer a sustainable solution for a wide range of applications, including remote monitoring systems, outdoor sensors, and off-grid electronics, enabling energy independence and reducing reliance on traditional power sources. With ongoing advancements in solar cell technology and system integration, solar panels are becoming increasingly efficient, affordable, and accessible, making them a promising solution for ultra-low power DC power needs.

In the example of FIG. 31, the exemplary switch (4100) includes an output conductor (4106) configured to provide a switch signal (4107). The switch signal (4107) described with reference to FIG. 31 provides an indication of the position or status of the switch. For example, a low voltage switch signal might indicate that the switch status is ‘OFF’ or ‘INACTIVE’, while a high voltage switch signal may indicate that the switch status is ‘ON’ or ‘ACTIVE’. Of course those of skill in the art will recognize that the switch signal need not merely be binary-either on or off. A switch signal may have a range of positions or statuses such as for example a first position, second position, third position and so on depending on the particular application into which a switch according to embodiments of the present invention is deployed. In such cases, to communicate more complex output signals than a binary ‘OFF’ or ‘ON’, the output conductor in such embodiments may be implemented as multiple signal lines collectively operating together as a signal bus. In other implementations, a single conductor may still be used but the switch signal might be composed of varying level of voltages to represent the multiple switch statuses. Still further, a single conductor may be also used to communicate non-binary switch positions through a pattern series of sub-signals over a discrete period of time, which taken together can be used to represent a variety of switch statuses.

The exemplary switch (4100) of FIG. 31 includes environmental sensors (4108) for measuring temperature and humidity. The environmental sensors (4108) of FIG. 31 are capable of generating an environmental signal (4111) in dependence upon the measured temperature and humidity that is communicated to the other parts of the exemplary switch (4100) via a sensor conductor (4110). Low power temperature and humidity sensors are essential components in a variety of applications where monitoring and controlling environmental conditions are crucial. These sensors are designed to accurately measure temperature and humidity levels while consuming minimal power, making them ideal for battery-powered devices, IoT systems, and other energy-constrained applications.

One key feature of low power temperature and humidity sensors is their ability to operate in sleep modes or low-power states when not actively measuring. Such sensors utilize power management techniques such as duty cycling or wake-on-demand functionality to conserve energy. By periodically waking up, taking measurements, and quickly returning to a low-power state, these sensors minimize power consumption while still providing timely and accurate environmental data.

Furthermore, low power temperature and humidity sensors often incorporate advanced sensing technologies and signal processing algorithms to optimize power efficiency. They may employ microelectromechanical systems (MEMS) or other miniaturized sensing elements that require minimal power to operate while maintaining high measurement accuracy. Additionally, these sensors utilize digital signal processing techniques to reduce noise, filter data, and compress information, enabling efficient data transmission and storage.

These sensors are typically designed with a focus on energy optimization, allowing them to operate for extended periods on limited power sources. This is particularly important in remote or wireless sensing applications where battery life is a critical factor. By leveraging low power consumption, intelligent power management, and advanced sensing technologies, low power temperature and humidity sensors enable continuous and reliable environmental monitoring while minimizing the energy footprint of the overall system.

As mentioned, conductors used in ultra-low power adjustable temperature-humidity sensor switches according to embodiments of the present invention may be made up of a single signal line or multiple signal lines, depending on the specific requirements of the application. The choice between using a single signal line or multiple signal lines is influenced by factors such as signal integrity, data transfer rates, noise immunity, and system complexity.

A single signal line, also known as a single-ended configuration, consists of a single conductor that carries the signal from the source to the destination. This approach is relatively simple and cost-effective since it requires fewer conductors. However, single-ended configurations are more susceptible to noise and interference due to the lack of a dedicated return path. The signal quality may degrade over long distances, and crosstalk between adjacent signals can occur. Single-ended configurations are commonly used in applications with lower data rates or shorter transmission distances where noise immunity is not a significant concern.

Multiple signal lines, on the other hand, often referred to as differential signaling or balanced signaling, involve the use of two or more conductors to transmit signals. These configurations typically employ a dedicated signal line and a complementary return or reference line. The signal is transmitted differentially, with the voltage between the two lines representing the desired signal. Differential signaling provides several advantages over single-ended configurations, including increased noise immunity, better common-mode rejection, and improved signal integrity. It enables higher data rates, longer transmission distances, and better resistance to external interference.

Multiple signal lines can also be used for specific purposes, such as transmission of parallel data or implementing bidirectional communication. In such cases, individual signal lines are allocated for each data bit or specific communication channel, allowing for simultaneous data transfer and increased bandwidth.

The choice between a single signal line or multiple signal lines depends on the specific requirements of the application. Single signal lines offer simplicity and cost-effectiveness but may be more susceptible to noise and interference. Multiple signal lines, on the other hand, provide enhanced noise immunity, better signal integrity, and increased data rates, making them suitable for high-speed and long-distance applications.

The environmental sensors (4108) in the batteryless ultra-low power adjustable temperature-humidity sensor switch (4100) of FIG. 31 generate environmental signals (4111) that corresponds to the measured temperature or humidity. These signals are an electrical outputs that varies in proportion to the temperature or humidity being sensed.

For the temperature sensing portion, the environmental sensor may use a thermistor, thermocouple, resistance temperature detector (RTD), or semiconductor-based sensor. As the ambient temperature changes, the sensor's electrical properties exhibit a corresponding change. This could be a change in resistance, voltage, or current depending on the specific sensor type. The circuitry within the sensor then converts this change in electrical properties into an analog or digital signal that represents the measured temperature. For example, a higher voltage or current may indicate a higher measured temperature.

Similarly, for humidity sensing, the environmental sensor likely uses a capacitive or resistive humidity sensor. Capacitive humidity sensors have a dielectric material between two electrodes whose capacitance changes with atmospheric moisture. Resistive humidity sensors measure the change in electrical impedance of a hygroscopic material in response to humidity. The sensor circuitry converts these electrical changes into an analog or digital humidity signal, with a higher signal level corresponding to higher relative humidity.

The exact nature of the environmental signal will depend on the specific sensor technologies and signal conditioning circuitry used. However, the key aspect is that the signal electrically encodes the measured temperature and/or humidity levels for further processing by the switch's comparison and output circuitry. These environmental signals (4111) in FIG. 31 allows the switch (4100) to open or close the switch output based on user-defined setpoints.

The use of a combined temperature-humidity sensor that generates a multi-variable environmental signal enables the switch to make control decisions based on either parameter individually or a combination of both. This provides flexibility to optimize the switch's operation for various applications like humidity control, temperature regulation, or comfort optimization.

In the example of FIG. 31, the exemplary switch (4100) includes an adjustable configuration module (4112) that allows a user to specify environmental threshold parameters (4113). Environmental threshold parameters (4113) of FIG. 31 are the thresholds, setpoints, or ranges against which an environmental signal (4111) is compared. Environmental threshold parameters (4113) of FIG. 31 consist of temperature threshold parameters (4114) and humidity threshold parameters (4115). For example, environmental threshold parameters may be implemented as temperature threshold parameter representing 80° degrees fahrenheit and used to trigger some action when a temperature sensor indicates that the ambient temperature rises above 80° degrees fahrenheit. Still further, environmental threshold parameters may be implemented as a humidity threshold parameter representing 30% humidity and used to trigger some action when a humidity sensor indicates that the ambient humidity rises above 30%. The environmental threshold parameters in the exemplary switch (4100) of FIG. 31 reflect temperature threshold parameters and humidity threshold parameters.

Temperature is a fundamental environmental characteristic that measures the average kinetic energy of the particles in a substance, typically expressed in degrees Celsius or Fahrenheit. Temperature sensor signals are compared with desired temperature parameters-ranges or setpoints—to determine if the measured temperature falls within an acceptable range. This comparison helps monitor and control temperature-dependent processes or environments. For instance, in HVAC systems, temperature sensors are used to maintain comfortable indoor temperatures by comparing the sensor signals with predefined temperature thresholds and adjusting heating or cooling systems accordingly.

Humidity, on the other hand, refers to the amount of moisture or water vapor present in the air. Humidity is commonly expressed as a percentage, representing the relative humidity (RH). Humidity sensor signals are compared with desired humidity parameters—levels or ranges—to assess whether the measured humidity falls within the desired range. This comparison is critical in various applications, including climate control, agriculture, and industrial processes. For instance, in a greenhouse, humidity sensors are used to monitor and maintain optimal humidity levels for plant growth by comparing the sensor signals with predefined humidity thresholds and activating humidifiers or ventilation systems as needed.

In both cases, the comparison of temperature and humidity parameters with sensor signals enables real-time monitoring, feedback control, and adjustments to maintain desired environmental conditions. This process helps ensure comfort, safety, and efficient operation in a wide range of applications, including building automation, weather forecasting, food storage, and manufacturing processes. Additionally, it allows for early detection of anomalies or deviations from the desired ranges, enabling proactive measures to prevent damage or optimize system performance.

Environmental parameters against which signals from environmental sensors are measured can dynamically change-rather than just be static-based on various factors, including the time of day, season, or specific environmental conditions. This dynamic adaptation is essential to account for the natural variations in the environment and optimize the monitoring and control systems accordingly.

One example of dynamic changes in environmental parameters is related to the time of day. For instance, in the case of temperature, different temperature setpoints may be defined for daytime and nighttime. During the day, when occupants are typically active, a lower temperature setpoint might be desired to maintain comfort. However, during the night when occupants are sleeping or when energy conservation is prioritized, a slightly higher temperature setpoint may be considered acceptable. By adjusting the temperature setpoints dynamically based on the time of day, energy efficiency can be enhanced without compromising comfort.

Similarly, environmental parameters can vary with seasons. In many regions, the climate and weather conditions fluctuate significantly throughout the year. For example, in HVAC systems, the desired temperature setpoints might be adjusted seasonally. During summer months, lower temperature setpoints are typically preferred to counteract heat and maintain a comfortable indoor environment. In contrast, during winter months, higher temperature setpoints are favored to provide sufficient warmth. These seasonal variations in temperature setpoints allow for adaptive control and efficient energy management.

Other factors, such as occupancy patterns, weather conditions, or specific environmental requirements, can also influence the dynamic changes in environmental parameters. For instance, in buildings with varying occupancy levels, temperature and humidity setpoints may be adjusted based on the presence or absence of occupants. Additionally, in applications like agricultural facilities or data centers, where specific environmental conditions are critical, the setpoints may be modified based on factors such as crop growth stages, equipment requirements, or data center cooling needs.

Overall, dynamically changing environmental parameters based on factors such as time of day, seasons, occupancy patterns, or specific requirements allows for adaptive and efficient monitoring and control of environmental systems. It ensures optimal comfort, energy savings, and environmental conditions in various settings, accommodating the natural variations and specific needs of the environment.

In the example of FIG. 31, the exemplary ultra-low power adjustable temperature-humidity sensor switch (4100) includes circuitry (4120) operatively connected to the power conductor (4104), the output conductor (4106), the environmental sensor (4108), and the adjustable configuration module (4112). The exemplary circuitry (4120) of FIG. 31 is implemented using a microcontroller and various other electrical components. Microcontrollers play a crucial role in the development of ultra-low power devices, providing the intelligence and control necessary to optimize power consumption and extend battery life. These specialized microcontrollers are designed to operate efficiently in energy-constrained applications where power efficiency is paramount.

Ultra-low power microcontrollers incorporate various features and techniques to minimize power consumption. Like other low-power components, microcontrollers may employ low-power sleep modes, allowing them to enter a deep sleep state when idle or inactive, thereby consuming minimal power. Wake-up sources, such as timers or external triggers, are utilized to bring the microcontroller back to an active state when needed. Additionally, these microcontrollers incorporate intelligent power management algorithms that dynamically adjust clock frequencies, voltage levels, and power delivery based on the operational requirements of the device.

Furthermore, ultra-low power microcontrollers are designed with low-power peripherals and optimized architectures. These peripherals, including analog-to-digital converters (ADCs), timers, and communication interfaces, are engineered to operate with minimal power consumption while still providing the necessary functionality. The microcontroller architectures are carefully designed to minimize power losses, optimize instruction execution, and enable efficient power gating of unused modules or peripherals.

The use of ultra-low power microcontrollers enables the development of energy-efficient devices across various domains, such as wearables, Internet of Things, medical devices, and remote sensors. These microcontrollers allow for extended battery life, reduced power supply requirements, and overall power optimization, making them well-suited for applications where energy efficiency is critical. As technology advances, microcontrollers continue to evolve, offering even lower power consumption, improved performance, and enhanced integration, enabling the realization of innovative and sustainable ultra-low power devices.

The circuitry (4120) of FIG. 31 sets the switch signal on the output conductor (4106) in dependence upon the environmental signals received from the environmental sensors (4108) and the environmental threshold parameters (4113) provided by the adjustable configuration module (4112). For example, the circuitry (4120) of FIG. 31 may compare the environmental signal received from the environmental sensor (4108) to see if it is above a threshold identified in the environmental parameters provided by the adjustable configuration module (4112). If the environmental signal received from the environmental sensor (4108) is above a threshold identified in the environmental parameters provided by the adjustable configuration module (4112), then the circuitry (4120) of FIG. 31 may set the switch signal on the output conductor (4106) to reflect that the switch (4100) is ‘ON’ or ‘ACTIVE’ as opposed to ‘OFF’ or ‘INACTIVE’.

In the example of FIG. 31, the output conductor (4106) is connected to and communicates the switch signal to a switch response circuitry (4122). This switch response circuitry (4122) of FIG. 31 takes some action based on the switch signal communicated through the output conductor. This switch response circuitry (4122) of FIG. 31 may be implemented in a variety of applications because the exemplary sensor switch (4100) can control a host of devices and systems, providing automated control based on environmental conditions. Here are a few examples of things that can be controlled using such the sensor switch (4100) in the example of FIG. 31:

1. HVAC Systems: The temperature humidity sensor switch can interface with heating, ventilation, and air conditioning (HVAC) systems to regulate temperature and humidity levels. It can activate or deactivate the HVAC system based on preset thresholds, ensuring optimal comfort and energy efficiency.

2. Ventilation Systems: In areas prone to excessive humidity, such as bathrooms, basements, or industrial spaces, the sensor switch can trigger ventilation systems to remove excess moisture. When the humidity exceeds a specified level, the switch can activate fans or open vents to promote air circulation and prevent mold or condensation issues.

3. Dehumidifiers/Humidifiers: The temperature humidity sensor switch can control standalone dehumidifiers or humidifiers. When the humidity level is too high, it can activate the dehumidifier to extract moisture from the air. Conversely, when the humidity is too low, it can trigger a humidifier to add moisture and maintain optimal humidity levels.

4. Greenhouses/Agricultural Systems: The sensor switch can be used in greenhouse environments to control temperature and humidity for plant growth. It can activate fans, misting systems, or shade curtains to regulate the microclimate, ensuring optimal conditions for plant health and productivity.

5. Data Centers: Temperature and humidity control are critical in data centers to ensure the optimal functioning of servers and equipment. The sensor switch can trigger cooling systems, such as air conditioners or precision cooling units, based on temperature and humidity thresholds, preventing overheating and equipment damage.

6. Energy Management Systems: By integrating with energy management systems, the sensor switch can provide inputs for energy optimization. It can control lighting systems, adjust thermostat setpoints, or trigger power-saving modes based on temperature and humidity readings, contributing to overall energy efficiency.

These are just a few examples of the wide range of applications where a low power temperature humidity sensor switch can provide automated control based on environmental conditions, ensuring comfort, energy efficiency, and optimal operation of various devices and systems.

In the example of FIG. 31, the circuitry (4120) is configured to set the switch signal (4107) only when the batteryless ultra-low power direct current power source (4102) provides sufficient power for the circuitry (4120) to operate, ensuring that the switch (4100) of FIG. 31 operates solely on the ultra-low power derived from the batteryless ultra-low power direct current power source. The components of the switch (4100) are configured to operate solely on ultra-low power derived from the batteryless ultra-low power direct current power source. That is, each of the environmental sensors (4108), adjustable configuration module (4112), and circuitry (4120) of FIG. 31 are configured to operate solely on ultra-low power derived from the batteryless ultra-low power direct current power source.

In the exemplary switch (4100) of FIG. 31, the circuitry (4120) may be configured to set the switch signal (4107) to a first state when both the temperature threshold parameter (4114) and the humidity threshold parameter (4115) are exceeded, and to a second state when either the temperature threshold parameter (4114) or the humidity threshold parameter (4115) is not exceeded. In other embodiments, the circuitry (4120) may be configured to set the switch signal (4107) to a first state when either the temperature threshold parameter (4114) or the humidity threshold parameter (4115) are exceeded.

In some embodiments, the environmental sensors (4108) of FIG. 31 may include a combined temperature and humidity sensor capable of generating a first environmental signal corresponding to temperature and a second environmental signal corresponding to humidity. In such embodiments, the circuitry (4120) is configured to set the switch signal based on a comparison of the first environmental signal to the temperature threshold parameter and a comparison of the second environmental signal to the humidity threshold parameter.

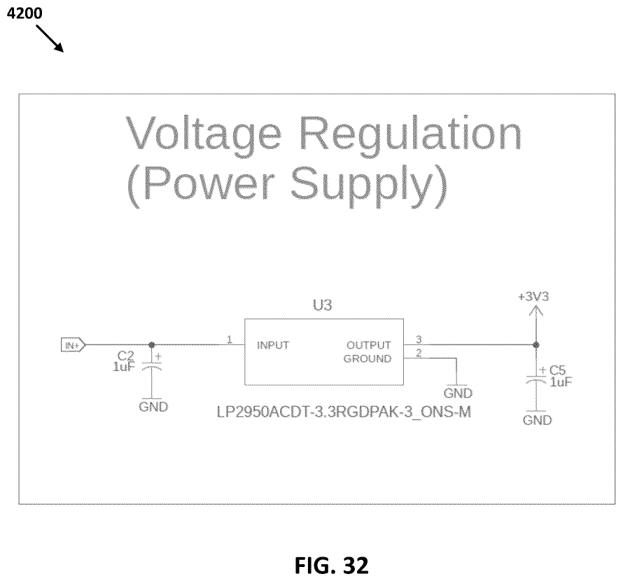

FIGS. 32-37 illustrate different implementations of the various components described with reference to FIG. 31. The various components described with reference to and shown in FIGS. 32-37 are part of an overall electrical schematic that has common identifying elements as will be recognized by one of skill in the art. FIG. 32 sets forth a block diagram illustrating an exemplary power supply (4200) useful in an ultra-low power adjustable temperature-humidity sensor switch according to embodiments of the present invention. The primary component of the exemplary power supply (4200) of FIG. 32 is the LP2950ACDT-3.3RG, which belongs to the LP2950 series of low dropout voltage regulators. It is specifically designed to provide a stable and regulated output voltage of 3.3 volts (3.3V). The component is available in a small surface-mount SOT-23 package, making it compact and suitable for space-constrained applications.

The LP2950ACDT-3.3RG regulator operates with an ultra-low dropout voltage, typically less than 100 mV at a 100 mA load. This characteristic allows it to regulate the output voltage even when the input voltage is only slightly higher than the desired output voltage. It is a versatile component with a wide input voltage range of 5.5V to 30V, making it compatible with various power sources, including batteries and other voltage supplies.

This voltage regulator is equipped with thermal shutdown and current limit protection features, which help safeguard connected devices and prevent damage due to excessive heat or current. It also exhibits excellent line and load regulation, ensuring a stable output voltage even in the presence of fluctuations in input voltage or varying load conditions.

The LP2950ACDT-3.3RG regulator finds applications in a wide range of electronic devices, including portable consumer electronics, battery-powered devices, IoT modules, and other low-power systems. Its compact size, low dropout voltage, and robust protection features make it a reliable choice for providing regulated power with minimal energy loss.

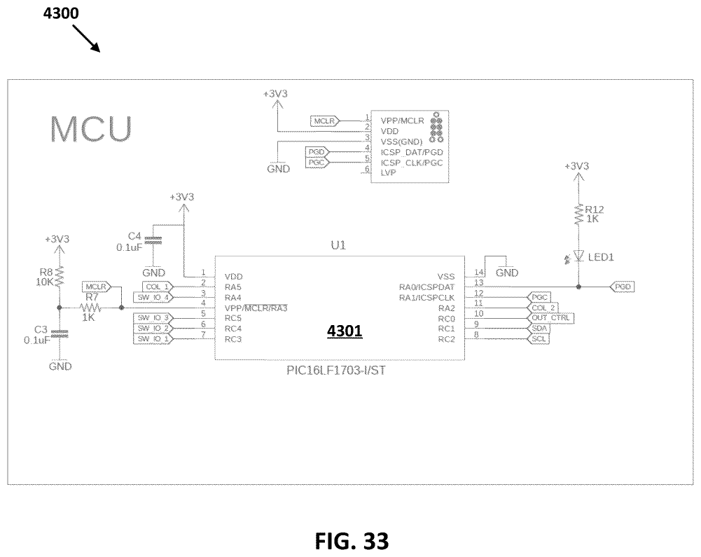

FIG. 33 sets forth a block diagram illustrating exemplary circuitry (4300) useful in an ultra-low power adjustable temperature-humidity sensor switch according to embodiments of the present invention. The main component in the exemplary circuitry (4300) of FIG. 33 is an ultra-low power microcontroller (4301). The exemplary microcontroller (4301) of FIG. 33 is implemented as the PIC16LF1703-I/ST, which is an electrical component that belongs to the PIC16 family of microcontrollers from Microchip Technology. It is a low-power, 8-bit microcontroller designed to offer a wide range of features and peripherals for various embedded applications.

The microcontroller (4301) of FIG. 33 is configured to compare the environmental signals to both the temperature threshold parameter and the humidity threshold parameter of the adjustable configuration module (4112 of FIG. 31), and to set the switch signal (4107 of FIG. 31) based on the comparison.

The component comes in a small 20-pin TSSOP package, making it suitable for space-constrained designs. The PIC16LF1703-I/ST microcontroller operates at a low power supply voltage and incorporates power-saving features such as multiple sleep modes and an ultra-low power consumption architecture. This makes it an excellent choice for battery-powered and energy-efficient applications.

Featuring a Flash program memory of 7.5 KB and a RAM of 256 bytes, the microcontroller offers ample space for program storage and data manipulation. It is equipped with a 10-bit ADC module, allowing for analog signal acquisition, and features multiple communication interfaces, including SPI, I2C, and USART, enabling seamless connectivity with other devices and peripherals.

The PIC16LF1703-I/ST microcontroller supports various industry-standard communication protocols and provides a comprehensive set of peripheral functions, including timers, PWM modules, and interrupts, to facilitate versatile application development. It offers flexibility and ease of programming using Microchip's MPLAB® Integrated Development Environment (IDE) and programming tools.

Overall, the PIC16LF1703-I/ST microcontroller is a versatile and power-efficient solution for a wide range of embedded applications, including IoT devices, home automation systems, sensor networks, and other low-power applications that require reliable and compact control capabilities. Its combination of low power consumption, ample memory, and rich peripheral integration makes it a popular choice among developers seeking cost-effective and energy-efficient microcontroller solutions.

The code written to operate the microcontroller illustrated in FIG. 33 is set forth in HEX format in Table 1 as follows:

TABLE 1

:020000040000FA
:020000001928BD
:100008007E1480310B1F17282100921D1028200014
:10001800921D10281A2617282100911D1728200044
:10002800911D17283D207E1009001A2841308400B0
:1000380085308500A03086000030870020300126FA
:1000480061308400853085002030860001308700CB
:1000580020300126F001F101F201F301F401F5016C
:10006800D630840000308500143007267E1020002A
:10007800952A200091112400951F62299513F301F8
:100088007008023E86008701010886008701810109
:10009800810AF00108002100D81808005708F80064
:1000A8007808F0005708860087010108F8007808EA
:1000B800F200570886008701413FF1000330F8003D
:1000C8007808D7075708EA3A031D6E28E730F80082
:1000D8007808D7005810570856060319D814240072
:1000E80016140230F8007808F3000800240096146B
:1000F8000230F8007808F30008002400161F8C2846
:100108000130F80078082100DA070430BF2508001C
:100118007508F9007408F800F936F80C7808240016
:100128009100741C9C280B30F8007808F300080034
:100138000330F8007808F30008002400161FAC28E4
:100148000130F80078082100DA070430BF250800DC
:1001580096147508F9007408F8007908F800F90190
:1001680006307805FA0000307905FB00F0307A0493
:10017800F40000307B04F50074142100DC01DC0A73
:100188000230F8007808F300080021005C03031926
:10019800DE28710886008701403FF400413FF500E2
:1001A800710886008701433FDE00710886008701D9
:1001B800423FDD00740824009100741CE8280530D3
:1001C800F8007808F30008000330F8007808F30016
:1001D80008002400161FFA280130F80078082100CA
:1001E800DA07240016130530BF2508000130210066
:1001F800DD025D0A031D12290430F8007808F107B2
:100208000130F202031D0B290030BF25080024002D
:1002180096140230F8007808F300080021005E0800
:10022800860087010108240091000130F800780851
:100238002100DE0708002400161F2C290130F800D1
:1002480078082100DA070430BF25240016130800B7
:1002580096150830F8007808F30008000830F80010
:100268007808F30024009615080024001108F80007
:1002780021005E0886008701780881000130F800B7
:100288007808DE070130DD0203195129240096128F
:100298000630F8007808F300542924009616D6256D
:1002A8002400161608000030BF2508000130F800A9
:1002B80078082100DA070630BF2508007308F8001F
:1002C800F9017908003A03196A295A29780884003B
:1002D8000C30040203185A298531E63004078200DD
:1002E80008002000E700FD30BB003B08E800FD30B7
:1002F800BB003B08E5006830BB003B08D400E901BF
:10030800EA01EB01EC016D030319BC29A701A70A57
:1003180021004D082000BB00BC013B08A8003C0898
:10032800A9006D30BD003D08AA006530F324A63051
:10033800890B9C290032023020006D06031DAF296D
:10034800323020006B066C04031908000130EB07FB
:100358000030EC3D9F296D080319BC29143069064B
:100368006A040319BC290130E9070030EA3D8729EE
:100378006D08031D08006D03031908000630BB0053
:100388003B08A70021004D082000BC00BD013C0827
:10039800A8003D08A9006D30BE003E08AA00403004
:1003A8001A25A630890BD6290032023020006D06A6
:1003B800031DE929323020006B066C04031908007C
:1003C8000130EB070030EC3DD9296D08031D8B2A5D
:1003D8004108BB00BC014008BD00BE013D08BE008D
:1003E800BD013B083D07D5003C083E3DD600D7017E
:1003F800D61BD7035708D8004408BB00BC014308E4
:10040800BD00BE013D08BE00BD013B083D07D90047
:100418003C083E3DDA00DB01DA1BDB035B08DC004D
:100428000030AF000030AE00FF30AD00FF30AC0050
:100438005808A3005708A2005608A1005508A000B4
:100448000030A7000030A6000130A5003B30A40012
:100458006D2420002308B3002208B2002108B1004F
:100468002008B000C923CF3020002C07DD00FF3062
:100478002D3DDE00FF302E3DDF00FF302F3DE00038
:100488000030AF000030AE00FF30AD00FF30AC00F0
:100498005C08A3005B08A2005A08A1005908A00044
:1004A8000030A7000030A6000030A5007D30A40071
:1004B8006D2420002308B3002208B2002108B100EF
:1004C8002008B000C923FA3020002C07E100FF30D3
:1004D8002D3DE200FF302E3DE300FF302F3DE400CC
:1004E8006708860087015D08C03F5E08C13F5F0856
:1004F800C23F6008C33F3A08860087016108C03FD1
:100508006208C13F6308C23F6408C33F0800143053
:1005180069066A04031908000130E9070030EA3D5A
:10052800BF290D268B170B172100951322000E14D7
:100538002100CC01CC0A0030D5000030D4000030B6
:10054800D3000030D2000030D1000030D00000309D
:10055800CF000030CE00CB01CA01CA0A0030C70064
:100568000030C6000030C5006430C400C901C801AD
:10057800C80A0030C3000030C2000030C100323069
:10058800C000FA25A3302100EA005530890BCA2A99
:10059800EA0BCA2ACE302100EA006A082000BA0015
:1005A800D23075216F232100EA006A08DB005B184E
:1005B800E02ACB01CB0AE12ACB015B1AE62AC90162
:1005C800C90AE72AC9012000EE01EF0121005B36C4
:1005D8000739EA00EB016A082000EE0021006B08E9
:1005E8002000EF006E082100EA000130EA35FF3EE6
:1005F800031DFA2A6A35A03E86008701403FC400E1
:10060800413FC500423FC600433FC7005B08EA00C0
:100618000530EA36890B0D2B6A080739EB00EC0127
:100628006B082000EE0021006C082000EF006E0827
:100638002100EA000130EA35FF3E031D1F2B6A3511
:10064800203E860001308700403FC000413FC10086
:10065800423FC200433FC30055084702031D3E2BDB
:1006680054084602031D3E2B53084502031D3E2B2A
:1006780052084402031C452B4B03031D452BCA019A
:10068800472BCA01CA0A51084302031D552B5008BB
:100698004202031D552B4F084102031D552B4E08DE
:1006A8004002031C5C2B4903031D5C2BC8015E2B15
:1006B800C801C80A4B0303194A080319692B4903DF
:1006C800031D6C2B4808031D6C2B22000E14C62A30
:1006D80022000E10C62A2000A10121008C16240039
:1006E8008C1221000C1524000C1121008E152400F9
:1006F8008E1521000E1624000E1621008E162400D9
:100708008E1621000C1624000C1621008C122200D3
:100718008C1220000C1A942B0130A0002008A1078D
:100728008E1A9A2B0230A0002008A1070E1AA02BBF
:100738000430A0002008A1078E19A62B0830A000BD
:100748002008A10721008C1624008C1221000C110E
:1007580022000C1120008E1AB52B1030A0002008A2
:10076800A1070C1ABB2B2030A0002008A1078E1966
:10077800C12B4030A0002008A1070E1AC72B8030DB
:10078800A0002008A1072108080000302000B800B8
:100798000030B7000030B6000030B5002F082E0436
:1007A8002D042C040319132CB901B90AAF1BE82B2B
:1007B8000130AC35ADODAEODAF0D890BDD2B013021
:1007C800B4003408B907DA2B0130B535B60DB70DCA
:1007D800B80D890BE92B2F083302031DFD2B2E08BA
:1007E8003202031DFD2B2D083102031DFD2B2C08A1
:1007F8003002031C082C2C08B0022D08B13B2E082F
:10080800B23B2F08B33B35140130AF36AE0CADOCFC
:10081800AC0C890B092C0130B902031DE82B3808F0
:10082800AF003708AE003608AD003508AC00080048
:100838002000A300210058185B2C02302000A200E1
:10084800210886008701220881002008A2002100D3
:10085800560A860087012000220881002308A2008A
:1008680021005608860087012000220881002108FF
:10087800A20021005608023E8600870120002208B7
:1008880081000330A20022082100D6075608EA3A60
:10089800031D542CE7302000A20022082100D600B6
:1008A800D81057085606031D612C5814612C2000D7
:1008B8002108860087018101810A2000210886001D
:1008C800870102300106031D080012262000911539
:1008D800080000302000AB000030AA000030A9005A
:1008E8000030A800201C802C2408A8072508A93D52
:1008F8002608AA3D2708AB3D0130A435A50DA60D55
:10090800A70D890B812C0130A336A20CA10CA00CD9
:10091800890B882C2308220421042004031D762C2B
:100928002B08A3002A08A2002908A1002808A00073
:100938000800043022008C0001308E0013302100A2
:100948008C003E308E0023008E0103308C00103066
:1009580024008C0038308E002100951725008C016A
:100968008E01373026008C003F308E003F30270044
:100978008C003F308E0011303C00A10011303D004A
:10098800A1001030A20012303C00A0000800200096
:10099800A6002308A5002208A400A435A50D260852
:1009A800860087012408C03F2508C13F2608860025
:1009B8008701013081044131003081042108A400FD
:1009C8002608023E86008701240881002008A4002A
:1009D8002608033E860087012408810008002000BD
:1009E800AD0021005818132D20002D08AB002B084E
:1009F800A0002708AC002C08A1002908A30028089B
:100A0800A200E3308125E3302000AB002B08A000D2
:100A18002A08AC002C08A10001301C240800200082
:100A28002A08860087018101810A08002000AD009C
:100A3800210058183A2D20002D08AB002B08A000E3
:100A48002708AC002C08A1002908A3002808A20048
:100A5800DF30CB24DF302000AB002B08A0002A08B1
:100A6800AC002C08A10001301C24080020002A0832
:100A7800860087018101810A08003C340034003473
:100A88000034463400340034003450340034003428
:100A980000345A34003400340034643400340034F0
:100AA80000346E34003400340034783400340034B8
:100AB80000348234003400340034143400340034F8
:100AC80000341E3400340034003428340034003438
:100AD800003432340034003400343C340034003400
:100AE80000344634003400340034503400340034C8
:100AF80000345A340034003400342000A60023089F
:100B0800A5002208A400A435A50D260886008701A3
:100B18002408C03F2508C13F2108A4002608023E3A
:100B280086008701240881002008A4002608033EC7
:100B380086008701240881000800E7302000A00013
:100B480020082100D700E7302000A000200821005D
:100B5800D600D8145810DA018030240094002830C8
:100B68009500970105309200200091119211210003
:100B7800911592150800F700240016157008023E1A
:100B88008600870101080319D42D7708F60070083C
:100B9800023E8600870101088600870176088100E9
:100BA800F30108000430F6007608F1070130F2027C
:100BB800031DE32D0430F6007608F3000800F30166
:100BC800F30A08004F287A28C928ED2857291F2931
:100BD8003229572939295A298128A1286230210028
:100BE80099009A01980122009601080044302000DB
:100BF800A00020082100CD000800FE0012001E0001
:100C0800FE0B022E0034640080010131890B082E8E
:100C180000349D24F2251626A1250800730803191F
:100C28000800122E163021009700080020009211AB
:020C38000800B2
:020000040001F9
:04000E00E4FFFFF21A
:00000001FF

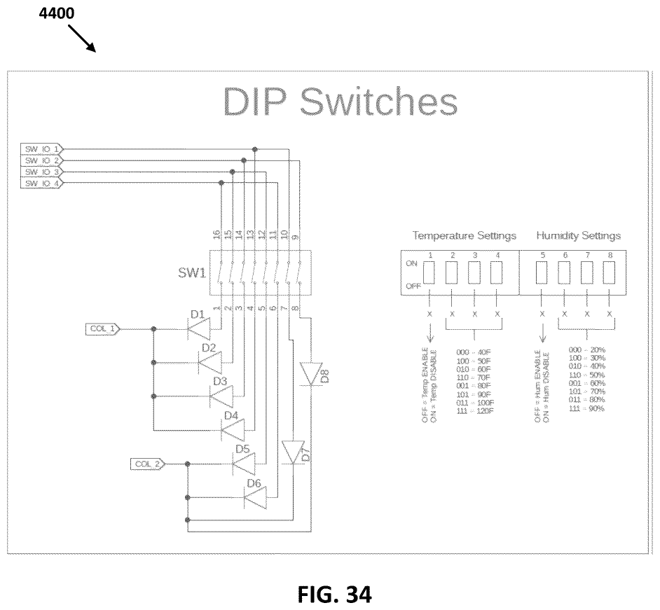

FIG. 34 sets forth a block diagram illustrating an exemplary adjustable configuration module (4400) useful in an ultra-low power adjustable temperature-humidity sensor switch according to embodiments of the present invention. The main component in the exemplary adjustable configuration module (4400) of FIG. 34 is the Switch DIP ON OFF SPST 8 Flush, which is an electrical component commonly used in electronic circuits and devices. This component is a DIP (Dual Inline Package) switch with SPST (Single Pole, Single Throw) configuration, which means it has one input terminal and one output terminal. The switch is designed to be flush-mounted, providing a neat and compact solution for applications where space is limited.

The switch features eight individual switches arranged in a row, each capable of independently toggling between the ON and OFF positions. This allows for selective control of various functions or settings within a circuit. The flush-mount design ensures that the switch sits flat against the circuit board, promoting a low-profile and streamlined appearance.

The Switch DIP ON OFF SPST 8 Flush finds widespread use in electronic devices, such as consumer electronics, computer peripherals, and industrial equipment. It provides a convenient and user-friendly means of enabling or disabling specific features or customizing device behavior. By simply toggling the individual switches, users can activate or deactivate specific functions or configurations as required. As illustrated in FIG. 34, switches 1-4 are used to specify temperature parameters selected from a range of adjustable thresholds: 40°, 50°, 60°, 70°, 80°, 90°, 100°, and 120°. Switches 5-8 are used to specify humidity parameters selected from a range of adjustable thresholds: 20%, 30%, 40%, 50%, 60%, 70%, 80%, and 90%.

Overall, the Switch DIP ON OFF SPST 8 Flush is a versatile and reliable component that offers easy and compact control capabilities for a range of electronic applications, allowing users to tailor the functionality of their devices to suit their specific needs.

In this way, the exemplary adjustable configuration module (4400) of FIG. 34 is implemented using user-adjustable switches. Each of the user-adjustable switches corresponds to a specific environmental threshold parameter-either temperature or humidity-allowing a technician or other user to set the environmental threshold parameters by manipulating the user-adjustable switches.

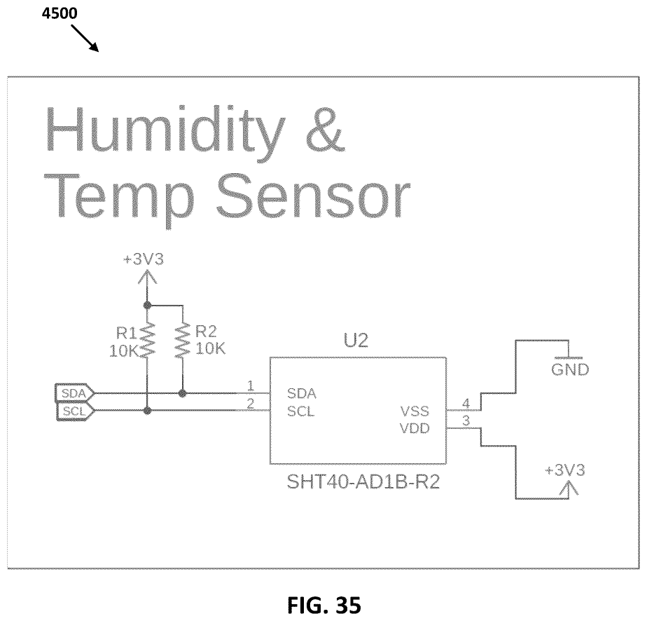

FIG. 35 sets forth a block diagram illustrating an exemplary environmental sensor (4500) useful in an ultra-low power adjustable temperature-humidity sensor switch according to embodiments of the present invention. The main component of the exemplary environmental sensor (4500) of FIG. 35 is the SHT40-AD1B-R2, which is an electrical component that belongs to the SHT4x series of digital humidity and temperature sensors from Sensirion. It is a high-precision sensor designed to provide accurate and reliable measurements of both relative humidity (RH) and temperature. The component is compact and comes in a surface-mount package, making it suitable for space-constrained applications.

The SHT40-AD1B-R2 sensor utilizes Sensirion's advanced CMOSens® technology, which integrates a sensing element, analog-to-digital converter, and digital interface into a single chip. This enables precise and direct digital output of temperature and humidity measurements, eliminating the need for additional signal conditioning circuitry.

With a wide operating voltage range of 1.62V to 3.6V, the sensor is compatible with various microcontrollers and systems. It offers high accuracy and repeatability, ensuring reliable performance across different environmental conditions. The SHT40-AD1B-R2 sensor features a fast response time and low power consumption, making it suitable for applications that require real-time monitoring and energy efficiency. It has low signal drift and hysteresis, providing stable and consistent measurements over time. This sensor is commonly used in a wide range of applications, including HVAC systems, weather stations, industrial automation, and consumer electronics. Its precise humidity and temperature measurements enable accurate climate control, process monitoring, and environmental sensing. The SHT40-AD1B-R2 sensor offers a reliable and cost-effective solution for capturing and monitoring critical environmental parameters in various industries and applications.

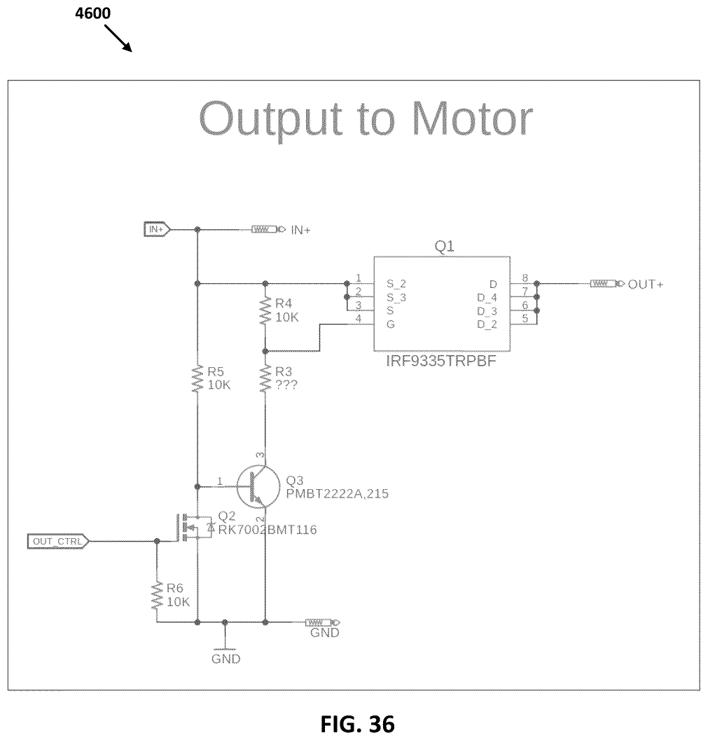

FIG. 36 sets forth a block diagram illustrating an exemplary switch response circuitry (4600) useful with an ultra-low power adjustable temperature-humidity sensor switch according to embodiments of the present invention. In the example of FIG. 36, the exemplary switch response circuitry (4600) turns on power to a motor that opens an attic vent and turns a fan to help hot air trapped in an attic space to escape into the atmosphere. The main component of the exemplary switch response circuitry (4600) of FIG. 36 is the IRF9335TRPBF, which is an electrical component that belongs to the IRF9335 series of P-channel power MOSFETs (Metal-Oxide-Semiconductor Field-Effect Transistors). It is designed to handle high power and voltage applications efficiently. The component comes in an 8-pin SO (Small Outline) package, providing case of integration into various electronic circuits and systems.

As a P-channel MOSFET, the IRF9335TRPBF is specifically designed for use in applications where it acts as a high-side switch, controlling the flow of current from the power supply to the load. It has a maximum voltage rating of 30V and a maximum continuous drain current rating of 5.4A.

The MOSFET features low on-resistance (RDS(on)) characteristics, resulting in minimal power dissipation and improved efficiency. This makes it suitable for high-power switching applications, such as motor control, power management, and load switching. The IRF9335TRPBF MOSFET also incorporates protection features such as thermal shutdown and overcurrent protection, safeguarding it from excessive heat and current stress.

Overall, the IRF9335TRPBF MOSFET is a reliable and high-performance component that provides efficient power switching capabilities in a compact package. Its ability to handle high voltage and current levels, along with its low on-resistance and built-in protection mechanisms, makes it well-suited for various demanding applications in industrial, automotive, and consumer electronics sectors.

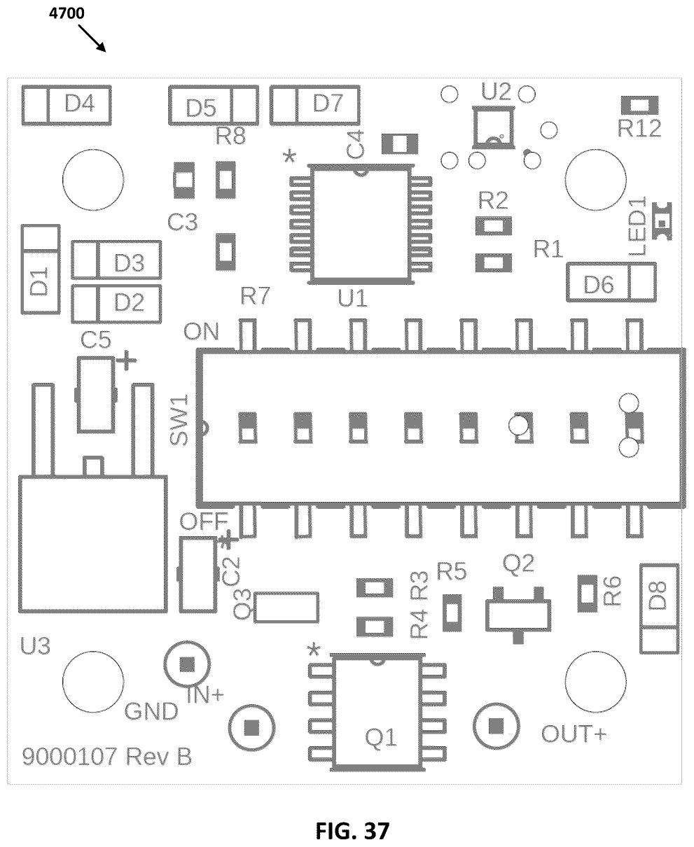

FIG. 37 sets forth a block diagram illustrating an exemplary printed circuit board (4700) for an ultra-low power adjustable temperature-humidity sensor switch according to embodiments of the present invention. The exemplary printed circuit board (4700) of FIG. 37 illustrates an exemplary configuration of the various components shown in and described with reference to FIGS. 2-6 as laid out on a printed circuit board. The components are identified in the table below:

| | | Reference |
|---|---|---|
| Part Number | Description | Designation |
| 9000107_REVB.ZIP | PCB | NA |
| 1551V1GY | Enclosure, Snap, Vented 1.5 | NA |
| 91772A076 | Screw, PanHead SS 2-56 × 3/16″ | NA |
| T491A105K035AT | CAP TANT 1UF 35 V 10% 1206 | C2, C5 |
| C0603C104M4RAC | cap cer 0.1UF 16 V 20% X7R 0603 | C3, C4 |
| BAS16GWJ | diode genpur 100 V0.215 A SOD123 | D1, D2, D3, D4, |
| | | D5, D6, D7, D8 |
| LTST-C191KRKT | LED red clear 0603 SMD | LED1 |
| IRF9335TRPBF | MOSFET P—CH 30 V 5.4 A 8SO | Q1 |
| RK7002BMT116 | MOSFET N—CH 60 V 250MA SST3 | Q2 |
| PMBT2222A, 215 | trans gp 40v 0.6 a 3pin SOT-23 | Q3 |
| RC0603FR-0710KL | res thick 10K Ohm 1% 1/10w0603 | R1, R2, R4, |
| | | R5, R6, R8 |
| CRCW06031K00JNEA | res thick 1.0KOhm 1/10w 5% 060 | R3, R7, R12 |
| 219-8LPST | Switch DIP ON OFF SPST 8 Flush | SW1 |
| PIC16LF1703-I/ST | 3.5KB FLASH, 256 B RAM, 10 B ADC | U1 |
| SHT40-AD1B-R2 | hum/temp sensor digital series | U2 |
| LP2950ACDT-3.3RG | LDO Reg Pos 3.3 V 0.1 A 3-pin | U3 |

Those of skill in the art will recognize that being able to set temperature and humidity parameters in an exemplary sensor switch according to embodiments of the present invention over Bluetooth or the internet brings several advantages in terms of convenience, flexibility, and remote control capabilities.

Firstly, this functionality allows technicians or users to adjust temperature and humidity settings from a remote location using their smartphones, tablets, or computers. Whether it is controlling the environment in a smart home, office, or industrial setting, users can conveniently access and modify the parameters without physically being present at the location. This remote control capability is particularly beneficial for situations where real-time adjustments are necessary, such as when unexpected changes in temperature or humidity occur or when specific environmental conditions need to be maintained for sensitive equipment or materials.

Secondly, the ability to set temperature and humidity parameters over Bluetooth or the internet provides flexibility and customization options. Users can define specific thresholds and setpoints that align with their preferences, comfort levels, or operational requirements. For example, in a smart home scenario, occupants can set the desired temperature and humidity levels according to their preferences, ensuring optimal comfort. In industrial or agricultural applications, operators can establish precise parameters for optimal production or crop growth, enhancing efficiency and yield.

Furthermore, this remote control capability enables automation and integration with other smart devices or systems. By connecting the sensor switch to a larger smart home or building automation system, temperature and humidity parameters can be adjusted automatically based on predefined schedules, occupancy patterns, or external environmental conditions. This integration allows for more advanced and energy-efficient control strategies, such as coordinating with HVAC systems or triggering alerts and notifications when specified thresholds are exceeded.

Overall, the ability to set temperature and humidity parameters in an exemplary sensor switch according to embodiments of the present invention over Bluetooth or the internet offers convenience, customization, and remote control capabilities. It enables technicians and other users to casily adjust and monitor environmental conditions from anywhere, promotes automation and integration with other smart devices, and provides enhanced control and optimization of temperature and humidity levels for various applications.

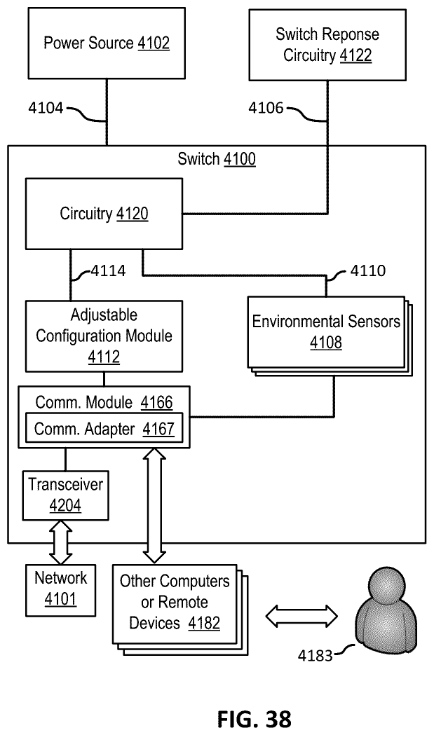

To allow such communication to occur, FIG. 38 sets forth a block diagram illustrating the exemplary ultra-low power adjustable temperature-humidity sensor switch (4100) according to embodiments of the present invention that includes a communications module (4166) having a communications adapter (4167) for data communications with other computers and remote devices (4182) and for data communications with a data communications network (4101) through a transceiver (4204). Such data communications may be carried out serially through RS-232 connections with other computers, through external buses such as a Universal Serial Bus (‘USB’), through data communications data communications networks such as IP data communications networks, and in other ways as will occur to those of skill in the art. Communications adapters implement the hardware level of data communications through which one computer sends data communications to another computer, directly or through a data communications network. Examples of communications adapters useful for in various embodiments of the present invention include modems for wired dial-up communications, Ethernet (IEEE 802.3) adapters for wired data communications network communications, and 802.11 adapters for wireless data communications network communications. The transceiver (4204) may be implemented using use a variety of technologies, alone or in combination, to establish wireline or wireless communication with network (4101) including, for example, Global System for Mobile Communications (GSM), General Packet Radio Service (GPRS), Code Division Multiple Access (CDMA), Evolution-Data Optimized (EV-DO), Enhanced Data Rates for GSM Evolution (EDGE), 3GSM, Digital Enhanced Cordless Telecommunications (DECT), Digital AMPS (IS-136/TDMA), Integrated Digital Enhanced Network (iDEN), IEEE 802.11 technology, Bluetooth, WiGig, WiMax, Iridium satellite communications technology, Globalstar satellite communications technology, Starlink satellite communications technology, or any other wireless communications technology as will occur to those of skill in the art.

The communications module (4166) of FIG. 38 is operatively coupled and communicates with the adjustable configuration module (4112) and environmental sensors (4108). In such a manner, the communications module (4166) may be used to send the environmental signals measured by the environmental sensors (4108) to other computers or users for monitoring or processing. The communications module (4166) of FIG. 38 may also be used to receive updates to the environmental threshold parameters of the adjustable configuration module (4112) from a remote device (4182) operated by a user (4183). Also, the communications module (4166) of FIG. 38 may also be used to receive software updates for embodiments of the adjustable configuration module (4112) implemented with a combination of hardware and software such as a microcontroller. As a manufacturer of an exemplary sensor switch (4100) creates new algorithms for determining the optimal switch settings or status in relation to the environmental signal provided by the environmental sensors (4108) or other configuration input signals, then the manufacturer could push software updates to the adjustable configuration module (4112) through the communications module (4166).

Being able to set temperature and humidity parameters in a sensor switch based on other inputs offers significant advantages in terms of adaptive control and tailored environmental management. By incorporating additional inputs, such as occupancy sensors, light sensors, or time-based triggers, the sensor switch can dynamically adjust temperature and humidity parameters to create a more optimized and personalized environment.

One advantage is energy efficiency. By considering occupancy and light levels, the sensor switch can intelligently adjust temperature and humidity settings based on the presence of occupants or natural lighting conditions. For example, if a room is unoccupied or natural sunlight provides sufficient warmth, the sensor switch can lower the temperature or adjust the humidity level to conserve energy. This adaptive control helps reduce unnecessary heating or cooling, resulting in energy savings and improved sustainability.

Another advantage is comfort and well-being. By incorporating time-based triggers, the sensor switch can adapt temperature and humidity parameters throughout the day to match occupants' preferences or specific activity requirements. For instance, in a workplace environment, the sensor switch can adjust the temperature and humidity levels during working hours to promote productivity and employee comfort. It can increase humidity in dry environments or adjust the temperature during peak activity times to create a comfortable and conducive atmosphere.

Additionally, incorporating other inputs allows for enhanced environmental control in specific applications. For example, in a greenhouse or indoor gardening setup, the sensor switch can integrate soil moisture sensors to dynamically adjust humidity parameters based on plant needs. This adaptive control ensures that plants receive the optimal moisture levels for healthy growth and prevents overwatering or underwatering.

Overall, the ability to set temperature and humidity parameters in a sensor switch based on other inputs enables adaptive control, energy efficiency, and personalized environments. By incorporating additional inputs, the sensor switch can dynamically adjust settings to optimize comfort, promote energy savings, and tailor environmental conditions to specific requirements, resulting in improved well-being, efficiency, and overall performance.

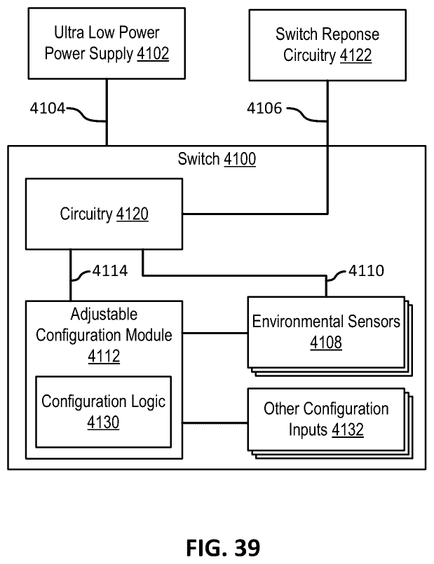

To allow for these other configuration inputs, FIG. 39 sets forth a block diagram illustrating another exemplary ultra-low power adjustable temperature-humidity sensor switch according to embodiments of the present invention that includes other configuration inputs (4132). The adjustable configuration module (4112) of FIG. 39 includes configuration logic (4130). The configuration logic (4130) of FIG. 39 may be implemented as a microcontroller with software to adjust the environmental parameters provided by the adjustable configuration module (4112) based on other configuration inputs (4132).

These other configuration inputs (4132) may be implemented as other sensors built into the switch (4100) such as, for example, timers to allow the configuration logic (4130) to take into account the time of day when adjusting the environmental parameters. These other configuration inputs (4132) may be implemented as signals or information received from other computers or over a network via a communications adapter such as the one described with reference to FIG. 38.

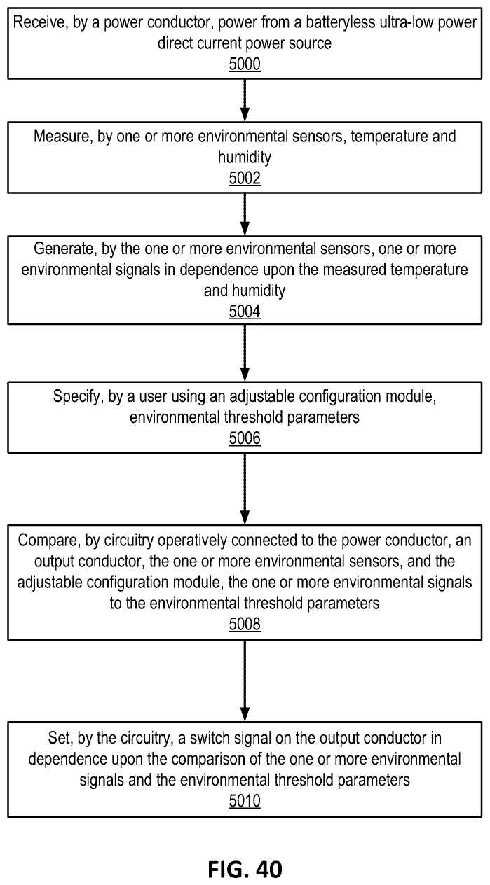

The present invention provides a method for controlling a batteryless ultra-low power adjustable temperature-humidity switch. The method leverages the unique features of the switch, including its ability to operate on ultra-low power from a batteryless direct current source, its integrated environmental sensors for measuring temperature and humidity, its user-adjustable threshold parameters, and its circuitry for comparing sensor readings to thresholds to generate a switch control signal. An exemplary method of batteryless ultra-low power adjustable temperature-humidity switching is described with reference to FIG. 40.

Turning to FIG. 40, the exemplary method of batteryless ultra-low power adjustable temperature-humidity switching of FIG. 40 begins by receiving (5000) power from a batteryless ultra-low power direct current power source, such as one or more solar cells, through a power conductor. This allows the switch to operate without relying on replaceable batteries, reducing maintenance requirements and environmental impact.

The exemplary method of batteryless ultra-low power adjustable temperature-humidity switching of FIG. 40 also includes measuring (5002) temperature and humidity using one or more environmental sensors integrated into the switch. These sensors generate (5004) one or more environmental signals that vary in response to changes in the measured temperature and humidity. For example, a temperature sensor may output a higher voltage signal as the ambient temperature rises, while a humidity sensor may exhibit a change in capacitance or resistance in response to changing moisture levels.

The exemplary method of FIG. 40 includes specifying (5006) environmental threshold parameters using the switch's adjustable configuration module. This module allows a user to input desired setpoints or ranges for temperature and humidity that define the switch's control behavior. For instance, the user might specify an upper temperature limit of 80° F. (26.7° C.) and a maximum humidity level of 60% relative humidity.

The switch's circuitry, which is operatively connected to the power conductor, output conductor, environmental sensors, and adjustable configuration module, performs the next step in the exemplary method of FIG. 40 by comparing (5008) the environmental signals to the user-specified threshold parameters. In the case of separate temperature and humidity signals, the circuitry compares each signal individually to its corresponding threshold. For a combined temperature-humidity sensor, the aggregate environmental signal is compared to a multi-variable threshold.

Based on the comparison results, the exemplary method of FIG. 40 involves setting (5010) the switch signal on the output conductor. If the measured temperature and humidity levels both exceed their respective thresholds, the switch signal is set to a first state to activate a connected device, such as a cooling system or dehumidifier. Conversely, if either the temperature or humidity is below its threshold, the switch signal is set to a second state to deactivate the connected device, thereby conserving energy.

The use of a batteryless power source in combination with ultra-low power operation enables the switch to provide long-term, maintenance-free environmental monitoring and control. The integration of user-adjustable thresholds allows the switch's behavior to be optimized for specific applications or seasonal variations. By comparing individual temperature and humidity signals to separate thresholds, the method offers precise control over environmental conditions.

In summary, the exemplary method of FIG. 40 offers an efficient and customizable approach to controlling a batteryless ultra-low power adjustable temperature-humidity switch. By leveraging the switch's innovative features and performing threshold comparisons, the method enables automated control of environmental systems for energy savings and optimal living conditions.

While the description above refers to particular embodiments of the present invention, it will be understood that many modifications may be made without departing from the spirit thereof. The accompanying claims are intended to cover such modifications as would fall within the true scope and spirit of the present invention. The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. A batteryless ultra-low power adjustable temperature-humidity sensor switch comprising:
a power conductor configured to receive power from a batteryless ultra-low power direct current power source;
an output conductor configured to provide a switch signal;
one or more environmental sensors for measuring temperature and humidity, the one or more environmental sensors capable of generating one or more environmental signals in dependence upon the measured temperature and humidity;
an adjustable configuration module that allows a user to specify environmental threshold parameters; and
circuitry operatively connected to the power conductor, the output conductor, the one or more environmental sensors, and the adjustable configuration module, wherein the circuitry is configured to set the switch signal in dependence upon the one or more environmental signals and the environmental threshold parameters.

2. The batteryless ultra-low power adjustable temperature-humidity sensor switch of claim 1 wherein the batteryless ultra-low power direct current power source comprises one or more solar cells.

3. The batteryless ultra-low power adjustable temperature-humidity sensor switch of claim 1 wherein the environmental threshold parameters comprise temperature threshold parameters.

4. The batteryless ultra-low power adjustable temperature-humidity sensor switch of claim 1 wherein the environmental threshold parameters comprise humidity threshold parameters.

5. The batteryless ultra-low power adjustable temperature-humidity sensor switch of claim 1 wherein the one or more environmental sensors are configured to operate solely on ultra-low power derived from the batteryless ultra-low power direct current power source.

6. The batteryless ultra-low power adjustable temperature-humidity sensor switch of claim 1 wherein the adjustable configuration module is configured to operate solely on ultra-low power derived from the batteryless ultra-low power direct current power source.

7. The batteryless ultra-low power adjustable temperature-humidity sensor switch of claim 1 wherein the circuitry is configured to operate solely on ultra-low power derived from the batteryless ultra-low power direct current power source.

8. The batteryless ultra-low power adjustable temperature-humidity sensor switch of claim 1 wherein the output conductor provides the switch signal to a motor, wherein the switch signal activates the motor.

9. The batteryless ultra-low power adjustable temperature-humidity sensor switch of claim 8 wherein the motor is part of an attic ventilation system, wherein the attic ventilation system is configured to turn on a fan upon activation of the motor by the switch signal.

10. The batteryless ultra-low power adjustable temperature-humidity sensor switch of claim 1, further comprising a communications module operatively connected to the adjustable configuration module, wherein the communications module is configured to receive updates to the environmental threshold parameters from a remote device operated by the user.

11. The batteryless ultra-low power adjustable temperature-humidity sensor switch of claim 1, wherein the adjustable configuration module comprises a plurality of user-adjustable switches, each of the plurality of user-adjustable switches corresponding to a specific environmental threshold parameter, allowing the user to set the environmental threshold parameters by manipulating the user-adjustable switches.

12. The batteryless ultra-low power adjustable temperature-humidity sensor switch of claim 1, wherein the circuitry is configured to set the switch signal only when the batteryless ultra-low power direct current power source provides sufficient power for the circuitry to operate, ensuring that the switch operates solely on the ultra-low power derived from the batteryless ultra-low power direct current power source.

13. The batteryless ultra-low power adjustable temperature-humidity sensor switch of claim 1, wherein:
the environmental threshold parameters comprise a temperature threshold parameter and a humidity threshold parameter; and
the circuitry comprises an ultra-low power microcontroller configured to compare the one or more environmental signals to both the temperature threshold parameter and the humidity threshold parameter, and to set the switch signal based on the comparison.

14. The batteryless ultra-low power adjustable temperature-humidity sensor switch of claim 1, wherein:
the environmental threshold parameters comprise a temperature threshold parameter and a humidity threshold parameter;
the adjustable configuration module is configured to allow the user to specify the temperature threshold parameter and the humidity threshold parameter; and
the circuitry is configured to set the switch signal to a first state when both the temperature threshold parameter and the humidity threshold parameter are exceeded, and to a second state when either the temperature threshold parameter or the humidity threshold parameter is not exceeded.

15. The batteryless ultra-low power adjustable temperature-humidity sensor switch of claim 1, wherein:
the environmental threshold parameters comprise a temperature threshold parameter and a humidity threshold parameter;
the adjustable configuration module is configured to allow the user to specify the temperature threshold parameter and the humidity threshold parameter; and
the circuitry is configured to set the switch signal to a first state when either the temperature threshold parameter or the humidity threshold parameter are exceeded.

16. The batteryless ultra-low power adjustable temperature-humidity sensor switch of claim 1, wherein:
the one or more environmental sensors comprise a combined temperature and humidity sensor capable of generating a first environmental signal corresponding to temperature and a second environmental signal corresponding to humidity;
the environmental threshold parameters comprise a temperature threshold parameter and a humidity threshold parameter; and
the circuitry is configured to set the switch signal based on a comparison of the first environmental signal to the temperature threshold parameter and a comparison of the second environmental signal to the humidity threshold parameter.

17. A batteryless ultra-low power adjustable temperature-humidity sensor switch comprising:
a power conductor configured to receive power from a batteryless ultra-low power direct current power source;
an output conductor configured to provide a switch signal to a motor of an attic ventilation system, wherein the attic ventilation system is configured to start a fan upon activation of the motor by the switch signal;
one or more environmental sensors for measuring temperature and humidity, the one or more environmental sensors capable of generating one or more environmental signals in dependence upon the measured temperature and humidity;
an adjustable configuration module that allows a user to specify environmental threshold parameters; and
circuitry operatively connected to the power conductor, the output conductor, the one or more environmental sensors, and the adjustable configuration module, wherein the circuitry is configured to set the switch signal in dependence upon the one or more environmental signals and the environmental threshold parameters.

18. The batteryless ultra-low power adjustable temperature-humidity sensor switch of claim 17 wherein the attic ventilation system comprises:
a base unit having a mounting platform for connecting the base unit to a surface having a surface opening, the base unit having a base collar extending away from the mounting platform, the base collar forming a perimeter of a base opening through the base unit that corresponds to the surface opening;
a fan unit comprising a fan housing and a fan, the fan housing configured to receive air through an inlet and expel the air through an outlet, the fan capable of connecting to a power source that enables the fan to move the air from the inlet to the outlet, wherein the fan housing further comprises a fan housing base;
a quick connect interface having a base feature and a fan housing feature, the base feature integrated into the base unit, the fan housing feature integrated into the fan unit, the base feature and the fan housing feature capable of detachably connecting together to secure the fan unit to the base unit, wherein the fan housing feature of the quick connect interface is integrated into the fan housing base.

19. A batteryless ultra-low power adjustable temperature-humidity switching method, the method comprising:
receiving, by a power conductor, power from a batteryless ultra-low power direct current power source;
measuring, by one or more environmental sensors, temperature and humidity;
generating, by the one or more environmental sensors, one or more environmental signals in dependence upon the measured temperature and humidity;
specifying, by a user using an adjustable configuration module, environmental threshold parameters;
comparing, by circuitry operatively connected to the power conductor, an output conductor, the one or more environmental sensors, and the adjustable configuration module, the one or more environmental signals to the environmental threshold parameters; and
setting, by the circuitry, a switch signal on the output conductor in dependence upon the comparison of the one or more environmental signals and the environmental threshold parameters.

20. The batteryless ultra-low power adjustable temperature-humidity switching method of claim 19, wherein:
the batteryless ultra-low power direct current power source comprises one or more solar cells;
the environmental threshold parameters comprise a temperature threshold parameter and a humidity threshold parameter;
comparing, by the circuitry, further comprises:
comparing a first environmental signal of the one or more environmental signals to the temperature threshold parameter, and
comparing a second environmental signal of the one or more environmental signals to the humidity threshold parameter; and
setting, by the circuitry, the switch signal further comprises:
setting the switch signal to a first state when both the first environmental signal exceeds the temperature threshold parameter and the second environmental signal exceeds the humidity threshold parameter, and
setting the switch signal to a second state when either the first environmental signal does not exceed the temperature threshold parameter or the second environmental signal does not exceed the humidity threshold parameter.
